(19) United States
(12) Patent Application Publication
(10) Pub. No.: US 2011/0253198 A1
(43) Pub. Date: Oct. 20, 2011

(54) LUMINESCENT SOLAR CONCENTRATOR

(75) Inventors: David Patrick, Bellingham, WA (US); Janelle Leger, Bellingham, WA (US); Stephen McDowall, Bellingham, WA (US); John Gilbertson, Bellingham, WA (US); Brad Johnson, Bellingham, WA (US)

(73) Assignee: WESTERN WASHINGTON UNIVERSITY, Bellingham, WA (US)

(21) Appl. No.: 13/041,259

(22) Filed: Mar. 4, 2011

Related U.S. Application Data
(60) Provisional application No. 61/310,617, filed on Mar. 4, 2010.

(51) Int. Cl. H01L 31/055; G02B 5/08

(52) U.S. Cl. 136/247; 359/850

(57) ABSTRACT

Luminescent solar concentrator (LSC) devices are provided herein. The provided LSCs include devices having an oriented luminophore in at least one layer of the LSC device. Other LSC devices include LSCs having both a collector wave guide, incorporating a luminophore, and a transport wave guide, having no luminophore, into which luminesced light from the collector wave guide travels. Additionally, wave guides for use in LSCs are provided that include guided-wave plasmon-polariton modes for improved optical transmission within LSC devices. The devices provided herein, either alone, or in combination, provide improved LSC device performance, particularly with regard to overall device efficiency.

### CROSS-REFERENCE TO RELATED APPLICATION

This application claims the benefit of U.S. Provisional Application No. 61/310617, filed Mar. 4, 2010, the disclosure of which is incorporated herein by reference in its entirety.

### STATEMENT OF GOVERNMENT LICENSE RIGHTS

This invention was made with Government support under DMR-1035512 awarded by the National Science Foundation. The Government has certain rights in the invention.

### BACKGROUND

Luminescent solar concentrators (LSCs) collect and concentrate sunlight for use in solar power generation. LSCs are devices typically consisting of a planar waveguide coated or impregnated with a fluorophore (or a phosphor). Sunlight absorbed by the fluorophore is re-emitted into the waveguide and concentrated at the edges of the collector for conversion to energy by a photocell. Unlike lens- and mirror-based concentrators, which require tracking systems to follow the sun's motion and can only concentrate direct, specular sunlight, LSCs are passive devices that work equally well with both diffuse and specular sunlight. They are therefore less costly to build, install, and maintain, are more readily integrated with a building's existing architectural elements, and can be used in climates where there is little direct sunlight. Because LSCs deliver “cool” photons, wavelength matched to the photovoltaic (PV) cell peak efficiency, there is reduced need for cooling to remove waste heat.

An exemplary LSC 10 is illustrated in FIG. 1, wherein the planar waveguide 12 comprises a plurality of fluorophores 15. The planar waveguide 12 is edge-coupled to PV cells 14 sensitive to the emission wavelength of the fluorophores 15. As shown in the detail of FIG. 1, the fluorophores 15 absorb light 16 of a first wavelength, and fluoresce to emit light 18 of a second, red-shifted, wavelength. The emitted light 18 is used to generate electrical current in the PV cells 14.

In combination with bandgap-matched, high-efficiency PV cells, LSCs offer the potential for a transformative reduction in the cost of solar electricity—by well over an order of magnitude. However, despite over three decades of research, LSCs thus far have had little practical impact. Early expectations were unmet as it became clear that performance was limited by poor fluorophore photostability and low efficiency. Conventional LSCs place extremely stringent requirements on the fluorophore: it should have high extinction across a broad portion of the solar spectrum, high quantum efficiency, high photostability, and most importantly, low self-absorption. Although progress has recently been made toward developing higher performing fluorescent systems for LSCs, currently available fluorophores can only satisfy some, but not all of these conditions. Consequently, the maximum energy concentrations Cₑ=(energy flux density out the concentrator edge)/(solar radiation flux density) achieved under broadband illumination has been Cₑ<10, well below the theoretical thermodynamic limit, Cₑ^{thermo}˜10⁴-10⁵.

The optical quantum efficiency (OQE) of an LSC, defined as the fraction of incident solar photons ultimately emitted from the concentrator edge, provides a useful metric for gauging how engineering dye orientation can improve performance. In an actual LSC, the OQE is usually limited by transport losses, with much of the sunlight falling near the center of the collector lost before reaching an edge. This is because as light travels in the waveguide it encounters additional fluorophores and may be re-absorbed and re-emitted multiple times. With each successive re-absorption/re-emission event, a certain fraction of photons (1-η_{φ}) is lost due to non-radiative relaxation processes, where η₁₀₀ is the photoluminescent quantum yield, and an additional fraction (1-ηₜᵣₐₚ) escapes out the top and bottom of the waveguide due to photons that were emitted at an angle inside the critical escape cone of the waveguide material. Although non-radiative losses can be made quite small by choosing a dye with a high quantum yield, escape cone losses are a serious problem. For example, an isotropic polymer or glass LSC with refractive index n=1.5˜1.7 will lose (1−ηₜᵣₐₚ)=20%˜30% of captured light out the top or bottom of the waveguide with each successive re-absorption and re-emission. Therefore in practice escape cone losses usually dominate all other losses in LSCs that are large enough to collect useful quantities of sunlight.

As a result, most previous work aimed at improved LSCs has focused on the incorporation of fluorophores with low self-absorption in order to maximize the distance photons travel before being re-absorbed. Usually this is accomplished through the selection of dyes with the largest possible Stoke's shift. However, this emphasis on self-absorption greatly restricts the types of dyes that can be used, making it difficult to satisfy the additional requirements of high photoluminescent quantum yield, solar and PV spectral matching, and good photochemical stability.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, a luminescent solar concentrator is provided. In one embodiment, the LSC comprises a plurality of waveguides,

said plurality of waveguides comprising at least one first isotropic waveguide and at least one first oriented waveguide,

said first isotropic waveguide comprising an isotropic plurality of first luminophores, each having a first absorption wavelength and a first emission wavelength,

said first oriented waveguide comprising an oriented plurality of second luminophores, each having a second absorption wavelength and a second emission wavelength.

In one aspect, a luminescent solar concentrator is provided. In one embodiment, the LSC comprises a waveguide having a first surface configured to receive electromagnetic radiation, at least one edge surface through which electromagnetic radiation can escape, and a plurality of aligned luminophores.

In one aspect, a luminescent solar concentrator is provided. In one embodiment, the LSC comprises:
(a) a collector waveguide comprising a luminophore having an emission wavelength, and a first surface configured to receive electromagnetic radiation, wherein the collector waveguide has a first optical loss at the emission wavelength; and
(b) a transport waveguide comprising a transport material in optical communication with a portion of the collector waveguide and at least one edge surface through which electromagnetic radiation can escape, wherein the transport waveguide has a second optical loss at the emission wavelength, and wherein the second optical loss is less than the first optical loss.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 illustrates a representative luminescent solar concentrator (LSC) as known in the prior art;

FIG. 2 illustrates a representative LSC having optically-oriented fluorescent luminophores in accordance with the provided embodiments;

FIG. 3 illustrates an exemplary coordinate system useful in determining the positioning of luminophores in relation to an LSC wave guide in accordance with the embodiments provided herein;

FIG. 4 illustrates an idealized LSC with luminophores having optimized absorption dipoles and emission dipoles in accordance with the embodiments provided herein;

FIG. 5 is a graph illustrating the fraction of photons emitted at angles that would trap them within a wave guide with a refractive index of 1.5 in accordance with simulated LSCs of the embodiments described herein;

FIG. 6A illustrates a model wave guide system used for theoretically determining the performance of LSCs in accordance with the embodiments provided herein;

FIG. 6B illustrates theoretical fluorophore absorption and emission spectra of a theoretical fluorophore useful in theoretically modeling the performance of LSC devices in accordance with the embodiments provided herein;

FIG. 7 illustrates the results of Monte Carlo simulations of LSC devices in accordance with the embodiments provided herein;

FIG. 8A illustrates a representative luminescent dye useful in the embodiments provided herein;

FIG. 8B illustrates a prototype LSC device in accordance with the embodiments provided herein;

FIG. 8C graphically illustrates a plot of internal quantum efficiency related to applied voltage for a representative LSC device in accordance with the embodiments provided herein;

FIG. 9 illustrates an exemplary reactive mesogen useful in orienting luminophores in accordance with the embodiments provided herein;

FIG. 10 schematically illustrates the alignment and covalent bonding of fluorophores into a reactive mesogen host in accordance with the embodiments provided herein;

FIG. 11 illustrates synthetic schemes for fluorescent monomers capable of being polymerized with reactive mesogens for use in the LSC devices provided herein;

FIG. 12 illustrates a chemical reaction scheme for producing a representative fluorophore useful in the embodiments provided herein;

FIG. 13 Illustrates a representative method for forming a waveguide having luminophores aligned by extrusion of a host plastic;

FIG. 14 graphically illustrates a hypothetical system for tuning emission of luminophores useful in the embodiments provided herein;

FIG. 15 illustrates a theoretical model prediction of absorption for a representative luminophore useful in the embodiments provided herein;

FIG. 16 illustrates a representative multi-layer LSC in accordance with the embodiments provided herein;

FIG. 17 illustrates a representative multi-layer LSC in accordance with the embodiments provided herein;

FIG. 18 illustrates a representative multi-layer LSC in accordance with the embodiments provided herein;

FIG. 19 illustrates a representative multi-layer LSC in accordance with the embodiments provided herein;

FIG. 20 illustrates a representative system for testing LSCs in accordance with the embodiments provided herein;

FIGS. 21A and 21B illustrate representative tandem wave guide luminescent solar concentrators (TW-LSC) in accordance with the embodiments provided herein;

FIG. 22 illustrates a representative apexed TW-LSC in accordance with the embodiments provided herein;

FIG. 23 illustrates a representative GWPPM wave guide configuration in accordance with the embodiments provided herein;

FIG. 24 graphically illustrates theoretical performance of a GWPPM wave guide in accordance with the embodiments provided herein;

FIG. 25 graphically illustrates the reflectance and frequency response of a GWPPM in accordance with the embodiments provided herein;

FIG. 26 graphically illustrates theoretical calculations of the electric field amplitude according to position within a representative GWPPM in accordance with the embodiments provided herein;

FIG. 27A illustrates the optical collection efficiency theoretically computed for a conventional LSC device;

FIG. 27B illustrates the collection efficiency theoretically calculated for a TW-LSC in accordance with the embodiments provided herein;

FIG. 28A illustrates a model system used in theoretically predicting the performance of LSC devices in accordance with the embodiments provided herein;

FIG. 28B graphically represents the theoretically calculated collection efficiency of an LSC in accordance with the embodiments provided herein; and

FIG. 29 illustrates a hypothetical “ideal” fluorophore useful in the embodiments provided herein.

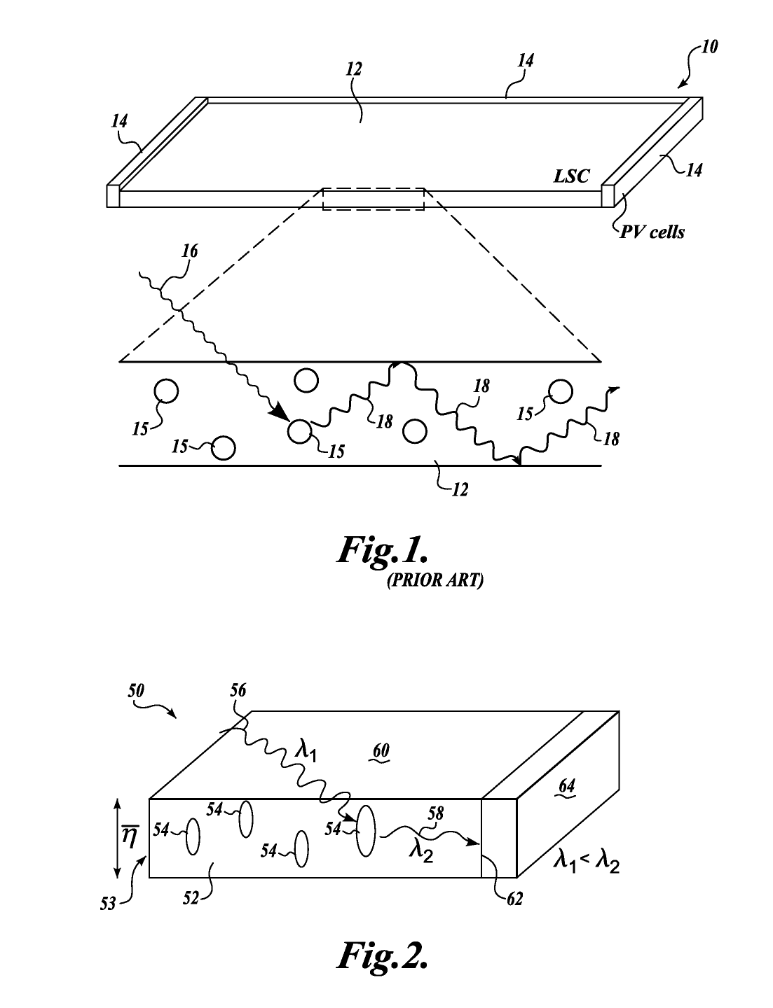

### DETAILED DESCRIPTION

Several improvements to luminescent solar concentrators (LSCs) are provided herein. These improvements can be used, either alone or in combination, to fabricate LSCs having enhanced performance in comparison to known LSC devices.

In one aspect, the invention provides LSCs having oriented luminophores (OLSCs). In certain embodiments, the luminophores are aligned to provide enhanced absorption of incident electromagnetic radiation, emission of luminescent radiation, or both. Exemplary luminophores include fluorophores and phosphors.

In a related aspect, the invention provides a multi-layer LSC (MLLSCs) having one waveguide layer with oriented luminophores and one or more additional waveguide layers having isotropic luminophores. In certain embodiments, the luminophores of the various layers of the LSC provide a cascading effect whereby the different luminophore layers are selected and arranged in the device such that the emission of one luminophore layer overlaps with the absorption of another luminophore layer, which in turn has an emission that overlaps with the absorption of a different luminophore layer, and so on. In certain embodiments, the luminophore layer with the longest emission wavelength includes oriented luminophores.

In another aspect, the invention provides tandem-waveguide LSCs (TWLSCs) that include a collector waveguide in optical communication with a transport waveguide. The collector waveguide acts as a traditional LSC in that it includes luminophores and directs luminesced light. The collector waveguide terminates (at least at one end) at the transport waveguide, which provides a low-absorption waveguide in relation to the collector waveguide. Typically, the transport waveguide does not contain luminophores. In a single TWLSC, multiple collector waveguides can be arranged around a single transport waveguide.

In yet another aspect, a low-loss waveguide is provided utilizing guided-wave plasmon-polariton modes (GWPPM). GWPPM waveguides provide low insertion losses at unidirectional insertion angles. Accordingly, GWPPM waveguides are useful, for example, as transport waveguides in TWLSCs.

In another embodiment, a solar cell (e.g., a photovoltaic cell) is optically coupled to at least the oriented waveguide of an LSC as provided herein. In yet another aspect, a method for generating electrical power comprising illuminating a luminescent solar concentrator of any of the other aspects is provided. In one embodiment, the electromagnetic radiation comprises the luminophore absorption peak wavelength.

These aspects of the invention will now be described in more detail below.

The LSC-related devices disclosed herein are typically described in terms of one or more planar waveguides. Depicting the devices as a planar waveguide (or a stack of planar waveguides) provides for simplified figures illustrating the devices. Additionally, for many of the disclosed devices, fabrication as a planar device will be the most efficient manufacturing method, and the most useful configuration. However, it will be appreciated that other device configurations, besides planar, are also contemplated by the invention. For example, devices can be fabricated based on fiber optic cables. Other shapes for the LSCs disclosed herein include rods, cylinders, and other gently curved forms, corrugated geometries, and pyramidal geometries. Furthermore, the LSC-related devices described herein are depicted as having square or rectangular shapes when viewed along a direction perpendicular to the major surface. However it will be appreciated that other device configurations, such as triangles and hexagons, are also contemplated by the invention (i.e. 2D shapes that tile the plane without gaps).

Furthermore, while the invention relates to luminophores, generally, the term “fluorophore” is used interchangeably herein to describe luminophores. Fluorophores are a preferred embodiment of the luminophores useful in the invention. Accordingly, any description related to fluorescence is generally applicable to luminescence (including phosphorescence).

### Optically Oriented Fluorescent Waveguides

In this aspect, LSCs are provided with a plurality of oriented luminophores in at least one waveguide layer of the device. The luminophores are oriented so as to optimize the absorbance and/or emission performance of the plurality of oriented luminophores acting in concert.

An exemplary device is illustrated diagrammatically in FIG. 2. The OLSC device 50 includes a waveguide layer 53 having a plurality of oriented luminophores 54 in a waveguide material 52. In certain embodiments, the luminophores 54 are “guests” in a “host” waveguide material 52 (i.e., a “guest-host” system), as illustrated in FIG. 2. In other embodiments, the entire waveguide layer 53 is formed from a single material that has the oriented luminophores 54 attached (e.g., conjugated) to the waveguide material 52.

The oriented luminophores 54 absorb incident light 56 and luminesce emitted light 58. The incident light 56 has a wavelength λ₁ and emitted light 58 has a wavelength λ₂ that is longer than λ₁.

As used herein, light of shorter wavelength is considered “blue,” “bluer,” or “blue-shifted” when compared to light of a longer wavelength, which is “red,” “redder,” or “red-shifted,” even if the specific wavelengths compared are not technically blue or red.

Referring still to FIG. 2, the luminophores 54 are aligned along a director axis n̅, which is perpendicular to the surface 60 of the waveguide layer 53, in the illustrated embodiment.

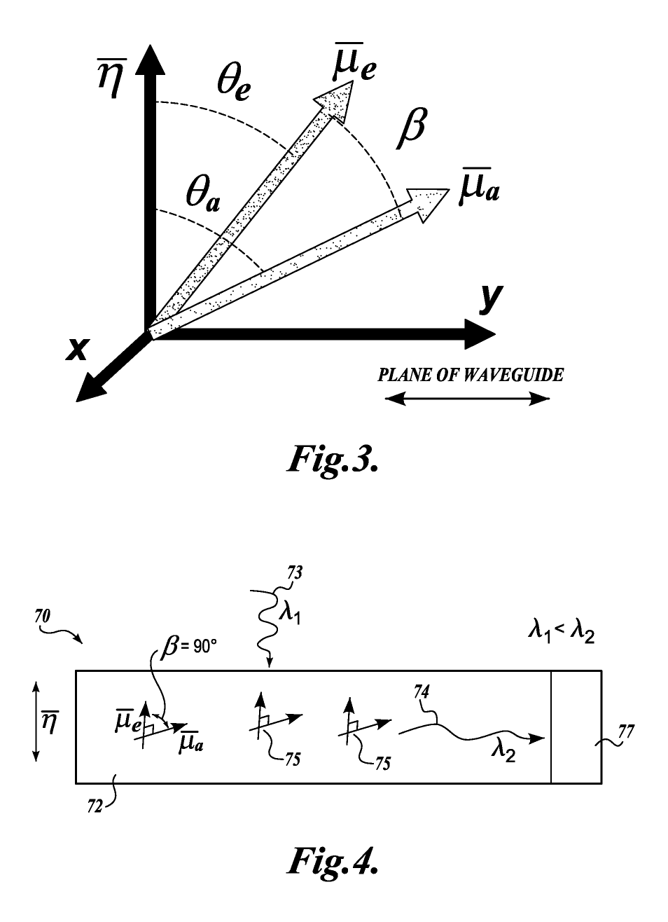

The alignment of the luminophores is produced using any of a number of techniques. A preferred method for aligning luminophores is the use of a system comprising luminophores incorporated into a liquid crystal (LC) made from “reactive mesogens” (RMs), which are small-molecule liquid crystalline monomers that can be photopolymerized to “lock in” orientational order. For example, films are applied as a thin layer on a glass substrate with matching refractive index. The fluorophore is made to orient along a chosen axis within the material through a combination of (i) control over the orientation of the RM director n̅, and (ii) suitable chemical modification of the dye. The preferred arrangement in most instances places the transition dipole μ̅ₑ associated with the S₁→S₀ emission perpendicular to the plane of the film (“homeotropic alignment”), so that emission occurs preferentially in the plane of the LSC waveguide (FIG. 3). This is advantageous for several reasons discussed below. The transition dipole μ̅ₐ associated with absorption S₁←S₀ then makes an average angle β with n̅, which for the exemplary perylene dyes is nearly constant over the entire visible spectrum.

The use of LCs as a host for aligning guest molecules therein is known to those of skill in the art. LCs are particularly susceptible to electric and/or magnetic fields, depending on the particular LC molecule or mixture used. LCs can also be aligned, for example, functionalizing the surface on which the LC is applied. Representative methods for using LCs as an alignment mechanism are set forth in U.S. Pat. Nos. 6,723,396 and 6,858,270, both of which are incorporated herein by reference in their entirety.

As used herein, with regard to planar waveguides, the planar surface (such as surface 60) is sometimes referred to as a “major surface” of the waveguide or device. A typical planar waveguide has two major surfaces (e.g., a top and bottom surface). A planar waveguide has minor surface at the edges. In a typical LSC based on a planar waveguide, light from the luminophores is collected by PVs in optical communication with the edge(s) of the LSC planar waveguide.

In the exemplary LSC illustrated in FIG. 2, the incident light 56 enters the waveguide layer 53 through the major surface 60. After conversion of the light via luminescence, the emitted light 58 is essentially trapped in the waveguide layer 53 by total internal reflection. A portion of the emitted light 58 travels through the waveguide layer 53 to an edge 62 of the waveguide layer 53 that is in optical communication (i.e., abutting, as illustrated) with a PV cell 64 configured to convert the emitted light 58 into electrical current.

The luminophores 54 illustrated in the exemplary embodiment of FIG. 2 are depicted in simplified form as ovals aligned with the director axis. In the present invention, the luminophores 54 may be aligned according to a molecular axis of the luminophore, an absorption dipole, μ̅ₐ of the luminophore, an emission dipole μ̅ₑ of the luminophore, or other molecular characteristic of the luminophore.

Alignment of luminophores normal to a major surface of an LSC is referred to herein as “homeotropic” or “normal” alignment.

The alignment of luminophores in the present invention may be better understood with reference to the coordinate system illustrated in FIG. 3. In the system of FIG. 3, the x and y axes are in the plane of the waveguide (e.g., waveguide layer 53). A luminophore (not explicitly illustrated) is aligned along its long molecular axis in the direction of the director axis n̅. The luminophore has an absorption dipole μ̅ₐ and emission dipole μ̅ₑ. The angle between the absorption dipole μ̅ₐ and the director axis n̅ is θₐ. The angle between the emission dipole μ̅ₑ and the director axis n̅ is θₑ. The angle between the absorption dipole μ̅ₐ and the emission dipole μ̅ₑ is β.

As can be seen in FIG. 3, the direction of the molecular axis does not necessarily align with the absorption dipole μ̅ₐ and the emission dipole μ̅ₑ. Each luminophore molecule will have a unique combination of μ̅ₐ, θₐ, μ̅ₑ, θ_{c}, and β, with respect to n̅.

An ideal LSC with luminophores having optimized absorption dipoles μ̅ₐ and the emission dipoles μ̅ₑ is illustrated in FIG. 4. The LSC 70 includes a waveguide layer 72 including a plurality of luminophores 75 illustrated symbolically by an absorption dipole μ̅ₐ and an emission dipole μ̅ₑ, with an angle β separating them. In the idealized system of FIG. 4, incident light 73 (λ₁) impinges on the luminophores 75 at an angle normal to the waveguide layer 72. The luminophores are uniformly oriented such that the absorption dipoles μ̅ᵤ extend in the plane of the waveguide layer 72 such that the absorption dipoles are normal to the incident light 73, a condition that provides for maximum absorbance of the incident light 73 by the luminophores 75.

Upon absorption of the incident light 73, the luminophores 75 luminesce emitted light 74 at a wavelength (λ₂) longer than the incident light. The emission dipoles μ̅ₑ are oriented such that the emitted light 74 is in the plane of the waveguide layer 72, which provides the optimal configuration for directing the emitted light 74 into a PV cell 77.

In the ideal luminophore configuration illustrated in FIG. 4, β˜90°, although such a configuration is not likely achievable in practical luminophores due to the constraints of engineering molecules having directionally divergent absorption and emission dipoles so as to create a system where β˜90°.

In the system of FIG. 4, when β˜90°, performance of such a device is enhanced further because the divergent directions of the absorption and emission dipoles essentially eliminates the possibility of one luminophore absorbing the emission of another, even if the luminophores have strongly overlapping emission and absorption bands, for reasons that are set forth below in the theory discussion.

While the director axis ( n̅) illustrated in FIGS. 2-4 is normal to the plane of the waveguide, it will be appreciated that any angle of director axis is possible in the present invention. However, for practical LSC devices formed from planar waveguides, luminophore orientation and design (i.e., with regard to μ̅ₐ, θₐ, μ̅ₑ, θₑ, and β) as close to the ideal system illustrated in FIG. 4 is preferred so as to optimize absorption and emission in the luminophore.

In one embodiment, β is an angle from 0° to 30°. More preferably, β is an angle greater than 30°.

The OLSC waveguide layer (e.g., waveguide layer 53) can be formed as a monolithic slab, or as a layer on a substrate. If the thickness and composition of the waveguide layer is not mechanically capable of self-support, then the waveguide layer is typically formed on a substrate. The substrate can be either a passive substrate that does not contribute in any way to the LSC (other than to provide mechanical support). Alternatively, the waveguide layer can be formed on a substrate that is itself a waveguide layer (e.g., containing luminophores or without luminophores), an electrode, a PV cell, a mirror, a scattering surface, or other component of an LSC.

Typical waveguide layer materials that are deposited on a substrate include guest-host systems where the luminophores are guests in a waveguide material host.

Luminophores useful in the LSCs provided herein are capable of being aligned based on some physical properties (such as long molecular axis). As set forth above, a large β value is preferable. Representative luminophores useful in the LSCs provided herein include perylene dyes; perylene diimmide dyes, including perylene-3,4,9,10-tetracarboxylic acid diimides, terylene diimide, and quaterrylene diimide; coumarin dyes, including borondipyrromethane (BODIPY) squaraine; and merocyanine dyes, including 4-dimethylamino-4′-cyano-stilbene.

One family of particularly useful red fluorophores are disclosed in U.S. Patent Application Publication No. 2010/0043878, the disclosure of which is incorporated herein by reference in its entirety.

Luminophores useful in the embodiments herein have a number of common fundamental properties. These characteristics include one or more of: (1) high photoluminescent quantum yield (η_{φ}), (2) either a wide spectral coverage with good photovoltaic responsivity matching or the ability to be combined with other dyes to provide a tandem set that has wide spectral coverage with good photovoltaic responsivity matching, and (3) high photostability. In addition to these fundamental properties, when considering a luminophore in a liquid crystal (LC) host, two other factors are of importance: orientability in the liquid crystal, and high solubility/absorptivity, as will be discussed further below.

Exemplary luminophores based on substituted perylene are provided below in the Examples section.

Host materials for the luminophores provide a matrix in which the luminophores can absorb and emit light. Typically, the host material will immobilize the luminophores in an aligned configuration. Such immobilization may be effect by, for example, the polymerization of a monomer for the host material, cooling a softened polymer, or crosslinking a polymer (e.g., using heat). Furthermore, the host material is optically transparent at the absorbance and emission wavelengths of the luminophores, so as to allow for maximum device efficiency at collecting and converting light into electrical current.

Representative host materials include polymers, such as polymethylmethacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene, methylmethacrylate-styrene copolymers, polyether sulphone, polysulphone, cellulose triacetate, and a variety of siloxane polymer formulations such as those made by Dow Corning (e.g., product numbers SR-7010, EG-6301,JCR-6175, and OE-6300), and polymers formed by polymerizing liquid-crystalline monomers.

In certain embodiments, liquid crystal (LC) mesogens are used as the host material in an LSC. In certain embodiments, the mesogens are reactive mesogens configured to polymerize (e.g., photopolymerize) so as to solidify and immobilize any guest luminophores. Typically, reactive mesogens are small molecule LC monomers such as RM82, RM257, RM256, RM141, RMS04-007, RMS04-073 (all from Merck Ltd.). As an alternative to the use of LCs as an alignment mechanism, in certain embodiment, the luminophore molecules are aligned using plastic extrusion and/or mechanical stretching. In mechanical stretching, dyes embedded in a bar or sheet of stretched plastic are in some circumstances aligned when the polymer is stretched, often by warming the plastic near its glass transition temperature, as is known in the literature. This is an alternative to extrusion. Extrusion is a plastic fabrication technique known to those of skill in the art. When extrusion is applied to a polymer containing luminophore molecules, the molecules are aligned in the direction of the extrusion. For example, an extruded bar or sheet of an acrylic polymer containing luminophore molecules will have the luminophore molecules parallel to the major plane of the bar. However, LSCs in certain embodiments of the invention require the luminophore molecules to be normal to the major plane of the bar, as described above.

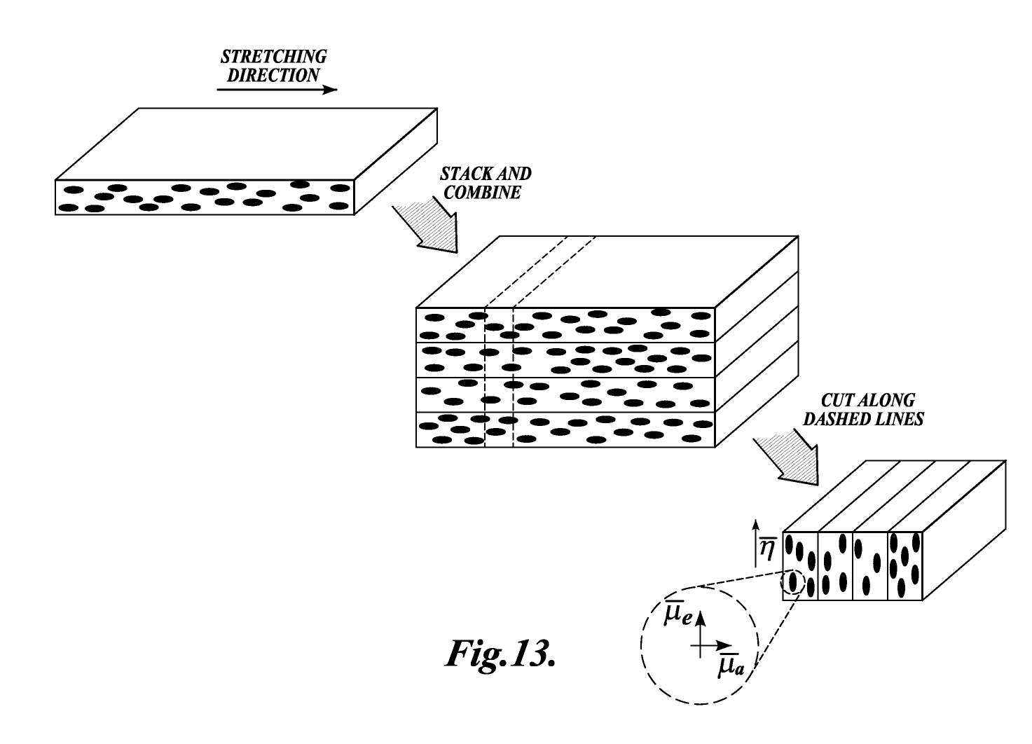

To solve this problem, a large number of stretched bars are fabricated, glued together face-to-face, and the resulting stack is cut transversely. A representative process for extrusion fabrication of aligned luminophores in a waveguide is illustrated in FIG. 13. In the process, a plurality of plastic bars having guest luminophores are fabricated using extrusion. The resulting bars have luminophores aligned in the plane of the waveguide. Several bars are then combined (e.g., using an adhesive) to form a stack. The stack is then cut transverse to the direction of the luminophore alignment. The resulting cut waveguide has luminophores aligned normal to the major surface of the waveguide. The waveguides can then be integrated into LSCs as described herein.

The method of FIG. 13 results in waveguides having segments where the boundaries between the stacked waveguides occur. These boundaries are potential sites for optical loss in the waveguides. However, loss at the boundaries can be minimized by having extremely flat and well-polished surfaces at the interface of the bars in the stack.

The polymer materials used for the extruded waveguides are preferably UV-transparent, optical-grade acrylic. This is acrylic that has no additives to block UV light. Plexiglas UVT acrylic resin, for example.

The luminophores used in the extruded waveguides can be any luminophores described herein or otherwise known to those of skill in the art.

In an exemplary embodiment, the stretched bars are at least 1″ wide. Thickness is not critical, but the thicker each bar is, the fewer needed to make a sufficient stack. The top and bottom faces are parallel and smooth.

The polymer chains and luminophore molecules may be partially oriented due to the flow of molten acrylic out the opening of the extruder die (the “draw”). The degree of orientational order as a result of this flow may be sufficient. Further orientation of the luminophores may also be required. The amount of orientational order, expressed in terms of an order parameter, S, depends on the draw ratio:

$$S = \frac{3 < {cos}^{2} θ > - 1}{2}$$

$$< {cos}^{2} θ > \approx \frac{{v}^{3}}{{v}^{3} - 1} + \frac{{v}^{3}}{{( {v}^{3} - 1 )}^{3 / 2}} arctan ( {( {v}^{3} - 1 )}^{1 / 2} ) ,$$

where v=L/Lₒ is the draw ratio. Lo=the undrawn (unstretched) length, L=the drawn length. The warm extrudate is elongated by the ratio L/Lo through the action of a take-off roller, which pulls the extrudate from the die opening. A representative draw ratio is from about 2 to about 10. The draw ratio can be controlled by the take-off speed. Because the dimensions of the extruded bar shrink as a result of drawing, the die opening has to be larger than the final product.

A plurality of bars are then arranged face-to-face and immobilized in a stack. A preferred method of immobilization is the use of an optically transparent adhesive (glue) whose refractive index preferably matches the extruded polymer.

The immobilized stack is then cut transversely using a saw, knife, or other means known to those of skill in the art.

Finally, the transverse-cut waveguide is polished, at least on the major planar surfaces, so as to reduce scattering loss during use of the waveguide in an LSC.

The waveguide can then be integrated into a LSC as described herein (e.g., attached to a PV cell and exposed to light of a wavelength corresponding to the luminophore integrated into the waveguide).

In one aspect, a luminescent solar concentrator is provided. In one embodiment, the LSC comprises a waveguide having a first surface configured to receive electromagnetic radiation, at least one edge surface through which electromagnetic radiation can escape, and a plurality of aligned luminophores.

In one embodiment, the plurality of aligned luminophores are aligned along a director axis selected from the group consisting of a long molecular axis of the molecularly aligned luminophores; an absorption dipole of the molecularly aligned luminophores; and an emission dipole of the molecularly aligned luminophores.

In one embodiment, the director axis is at an angle relative to the first surface selected from the group consisting of perpendicular, parallel, and an angle therebetween.

In one embodiment, the director is at an angle relative to the at least one edge surface selected from the group consisting of perpendicular, parallel, and an angle therebetween.

In one embodiment, the director axis is the emission dipole and is oriented perpendicular to the first surface, and wherein the absorption dipole is perpendicular to the emission dipole.

### Multi-Layer Luminescent Solar Concentrators

In another aspect, the invention provides a multi-layer LSC (MLLSCs) having one waveguide layer with oriented luminophores and one or more additional waveguide layers having isotropic luminophores. Embodiments of this aspect incorporate the orientation of luminophores as described above with reference to oriented LSCs (OLSCs). More specifically, embodiments of this aspect include at least one waveguide layer having oriented luminophores. The oriented waveguide layer of the present aspect is one of a plurality of layers in a multiple waveguide LSC.

In one aspect, a luminescent solar concentrator is provided. In one embodiment, the LSC includes a plurality of waveguides. In one embodiment, the plurality of waveguides includes at least one first isotropic waveguide and at least one first oriented waveguide. The first isotropic waveguide includes an isotropic plurality of first luminophores, each having a first absorption wavelength and a first emission wavelength. The first oriented waveguide includes an oriented plurality of second luminophores, each having a second absorption wavelength and a second emission wavelength.

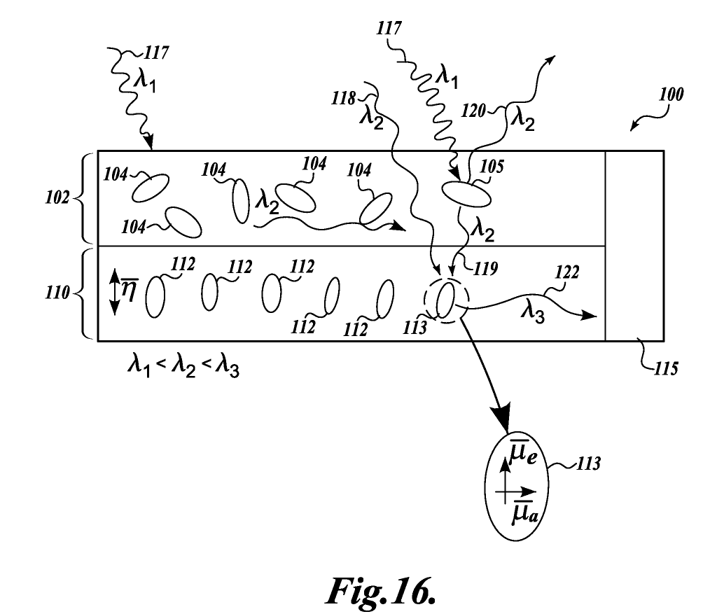

A representative LSC in accordance with the embodiments provided herein is illustrated in a diagrammatic edge-view cross section in FIG. 16. The LSC 100 includes a first isotropic waveguide 102, a first oriented waveguide 110, and a photovoltaic cell 115. The first isotropic waveguide 102 is arranged in a planar stack with the first oriented waveguide 110. The photovoltaic cell 115 abuts the end face of both the first isotropic waveguide and the first oriented waveguide 110.

Still referring to FIG. 16, the first isotropic waveguide 102 includes a plurality of luminophores 104 and 105 disposed isotropically within the first isotropic waveguide 102 layer. As set forth above with regard to FIG. 2, the luminophores 104 and 105 can be guests in a guest-host matrix or can be conjugated with the waveguide material.

Referring still to FIG. 16, the first oriented waveguide 110 includes a plurality of oriented luminophores 112 and 113 aligned along a director n̅. Similar to the luminophores 104 and 105, the luminophores 112 and 113 can be either guests or covalently conjugated to the waveguide material. The LSC of FIG. 16 operates when incident light 117 (λ₁) and 118 (λ₂) impinges on the device (e.g., a major surface of the device) so as to cause the luminophores 104, 105, 112, and 113 to luminesce and produce light that is either directly converted to electricity using the photovoltaic cell 115 or transferred to other luminophores which then luminesce again to create light that is transferred into electrical current by the photovoltaic cell 115.

In the exemplary embodiment illustrated in FIG. 16, light of two wavelengths is illustrated impinging on the device. Light 117 has a wavelength λ₁ and light 118 has a wavelength λ₂. In the illustrated embodiment, λ₂ is greater λ₁ (e.g., λ₁ is blue light, and λ₂ is orange light). While the embodiment illustrated in FIG. 16 includes the light 117 and 118 impinging on the isotropic waveguide 102, it will be appreciated that the invention is not limited to such an arrangement, and the oriented waveguide 110 could be the “top” surface at which the light first impinges on the device 100 in other embodiments.

Referring specifically to the light 117 impinging on the isotropic luminophore 105, the illustrated embodiment shows the isotropic luminophore 105 luminescing to emit light 119 and 120 at a wavelength λ₂. As illustrated, the light 119 and 120 can be emitted in any direction. The light 119 is emitted from the luminophore 105 at wavelength λ₂ in the direction of the first oriented waveguide 110 and, specifically, oriented luminophore 113. Oriented luminophore 113 absorbs the light 119 at λ₂ and luminesces to emit light 122 at λ₃, a wavelength longer than λ₂. As illustrated in the detail of oriented luminophore 113, the luminophore has an absorption dipole axis ( n̅ₐ) parallel to the plane of the first oriented waveguide 110 and an emission dipole axis normal to the plane of the first oriented waveguide 110. Because the oriented luminophore 113 is oriented along the director n̅ and the emission dipole axis n̅ₑ is in the same direction as the director n̅, the light 122 is emitted preferentially in the plane of the first oriented waveguide 110 so as to travel either directly toward the photovoltaic cell 115 or directly away.

In addition to the process described above, light 118 of wavelength λ₂ also can penetrate directly through the first isotropic waveguide 102 into the first oriented waveguide 110 so as to absorb into the oriented luminophore 113 to produce light 122 of wavelength λ₃. Accordingly, in the illustrated embodiment of FIG. 16, the LSC device 100 converts light λ₁, λ₂, and λ₃ into electrical current at the photovoltaic cell 115 through the illustrated mechanisms. The orientation of the oriented luminophores 112 and 113, combined with the specific configuration of the absorption dipole axis and emission dipole axis of the oriented luminophores 112 and 113, results in a maximum amount of light 118 and 119 at λ₂ absorbed into the oriented luminophores 112 and 113, and also a maximum amount of emitted light 122 at λ₃ luminesced from the oriented luminophores 112 and 113 and delivered to the photovoltaic cell 115. Accordingly, the orientation of the luminophores 112 and 113 provides a more efficient device compared to a device having only isotropic luminophores.

In one embodiment, the reddest layers are oriented and bound bluer layers at the top and bottom of the stack of waveguides. Such a configuration is beneficial because the oriented red layer on the outside can capture emitted blue light from inner layer(s) before the blue light escapes.

In a device with one oriented layer, this advantage remains. However even more of the fluoresced blue light from the core would be captured if either (1) there was a second oriented skin on the bottom, or (2) a mirror or diffuse scattering surface was placed on the bottom. In case (2) the mirror or scattering surface should be separated from the waveguide by a low-index material or air gap, because reflection by TIR is more efficient than reflection by any mirror.

For example, the configuration in FIG. 16 could be advantageous if the oriented layer was sensitive to direct sunlight (e.g., UV exposure), or weathering, etc., necessitating the intervening isotropic layer to shield the oriented layer from the elements. Also, if a mirror is placed beneath the device (or on top, as it is drawn in FIG. 16), only 1 oriented red layer is needed. A device with a single oriented layer is presumably less expensive that one with two.

In certain embodiments, the luminophores of the various layers of the MLLSC provide a cascading effect whereby the different luminophore layers are selected and arranged in the device such that the emission of one luminophore layer overlaps with the absorption of another luminophore layer, which in turn has an emission that overlaps with the absorption of a different luminophore layer, and so on.

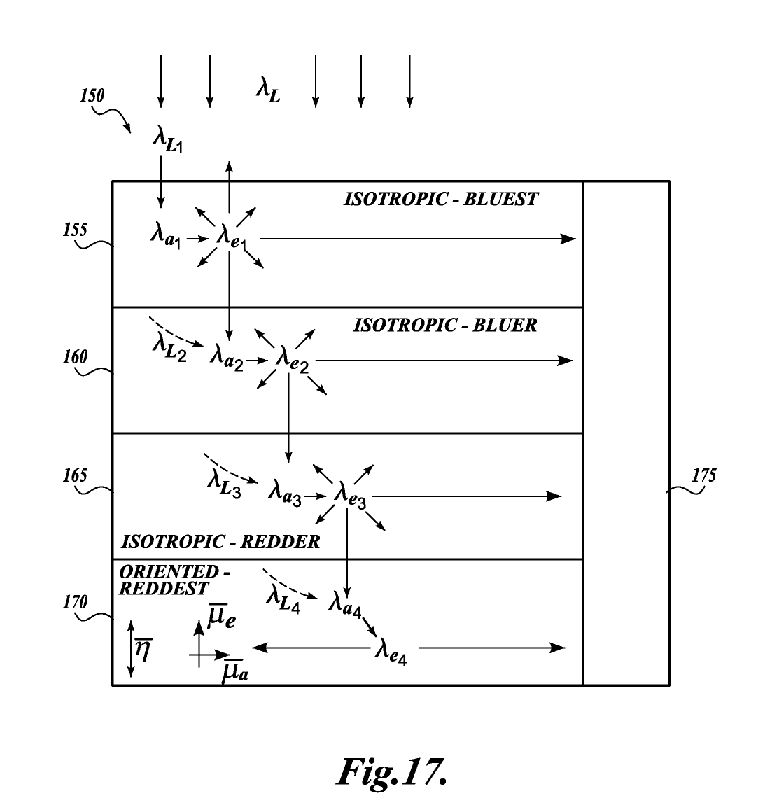

Referring now to FIG. 17, a multilayer LSC device 150 is illustrated wherein a number of isotropic waveguide layers 155, 160, and 165 are arranged in a stack on top of an oriented luminophore layer 170. Light of broad spectrum wavelengths is impinged on the device, and the luminophore layers 155, 160, 165, and 170 absorb and luminesce to direct light into the photovoltaic cell 175 to produce electrical current. The impinging light in the illustrated embodiment has at least light of wavelength λ_{L1}, but may be a broader light source (e.g., white light source) containing any number of wavelengths of light. However, for simplicity, the device 150 illustrated in FIG. 17 primarily describes the device with regard to input of light of wavelength λ_{L1}.

The layer 155, 160, 165, and 170 of the device 150 are arranged from “bluest” (155) to “reddest” (170), although it will be appreciated these terms are not indicative of the actual color of absorption or emission of the layer, but only indicating that the “bluest” is the shortest wavelength of light (e.g., emitted light), and the “reddest” is the light having the longest emission wavelength.

The layers of the device 150 in FIG. 17 begin at the layer closest to the source of light, which is layer 155, the bluest layer. Layer 155 is isotropic, meaning that the luminophores within the layer 155 are isotropic (i.e., not oriented). The luminophores in layer 155 have an absorption at wavelength λₐ₁ and a luminescent emission at wavelength λₑ₁.

Layer 160 of the device 150 is isotropic and is “bluer” in relation to layers 165 and 170. The luminophores of the layer 160 have an absorption at wavelength λₐ₂ and a luminescent emission at λₑ₂.

Layer 165 of the device 150 is an isotropic layer wherein the luminophores are “redder” than the blue layers 155 and 160. The isotropic luminophores of layer 165 have an absorption at λₐ₃ and a luminescent emission at λₑ₃.

Layer 170 of the device 150 includes oriented luminophores having the reddest emission of any of the layers of any of the device 150. The luminophores are oriented along a director n̅ in a direction normal to the plane of the layer 170. The emission and absorption dipole axes are normal to each other, with the emission dipole being normal to the plane of the layer and the absorption dipole being parallel to the plane of the layer.

The device 150 harvests the energy of the incoming light λ_{L} according to at least the following exemplary description of operation. Initially, light of wavelength λ_{L1} impinges on the bluest isotropic layer 155. The absorption λₐ₁ of the bluest layer 155 overlaps with the wavelength of the incident light λ_{L1}, thus causing the luminophore to luminesce and emit light of wavelength λₑ₁. Because the luminophores of the layer 155 are isotropic, the light at λₑ₁ is emitted in all directions, including some light that reaches the photovoltaic cell 175, some light that will emit back toward the light source, and some light that will emit in the direction of the bluer isotropic layer 160.

Light of wavelength λₑ₁ that crosses from the bluest layer 155 to the bluer layer 160 impinges on the luminophores in the bluer layer 160. The absorption wavelength λₐ₂ of the luminophores of the bluer layer 160 overlap λₑ₁, causing luminescence at λₑ₂, once again in all directions because the luminophores in the bluer layer 160 are isotropic.

Light of wavelength λₑ₂ that crosses from the bluer layer 160 into the redder layer 165 is absorbed at wavelength λₐ₃, which overlaps with λₑ₂. The luminophores in the redder layer 165 luminesce at wavelength λₑ₃ in all directions because the luminophores are isotropic.

Light emitted from the redder layer 165 at wavelength λₑ₃ that crosses into the oriented reddest layer 170 will be absorbed by the oriented luminophores at wavelength λₐ₄, which overlaps λₑ₃. The luminophores then luminesce at wavelength λₑ₄. Because the luminophores in the oriented reddest layer 170 are oriented according to their emission and absorption dipoles, the light at wavelength λₑ₄ is preferentially emitted in the plane of the layer, and therefore travels either toward or away from the photovoltaic cell 175. Notably, light emitted at wavelength λₑ₄ does not emit in a direction either toward layer 165 or away from the device (toward the “bottom” of the device illustrated in FIG. 17). Accordingly, the oriented reddest layer 170 acts as a barrier for containing light within the device 150 at the bottom edge.

If the source of light is a broader wavelength source (e.g., white light), it will be appreciated that the luminophores in layers 160, 165, and 170 need not only harvest light directly from the layers preceding them in the energy cascade, but can also absorb and luminesce based on light directly impinging on the luminophores at the absorption wavelength. This effect is illustrated in FIG. 17 with the dashed arrows in layers 160, 165, and 170, wherein light of wavelength λ_{L2} can optionally impinge on the luminophores in the isotropic bluer layer 160; light of wavelength λ_{L3} can optionally impinge on the isotropic redder luminophores in layer 165, and light of wavelength λ_{L4} can optionally impinge on the oriented reddest luminophores in oriented reddest layer 170.

While FIG. 17, and subsequent figures, describe LSC devices having multiple layers of isotropic luminophores wherein each layer includes a single luminophore, it will be appreciated that a single waveguide layer can include multiple luminophores. Particularly, a plurality of species of isotropic luminophores, each having a different absorption and emission wavelength, can be incorporated into a single waveguide layer. For example, the MLLSC of FIG. 17 could be simplified into a two-layer LSC device by combining the luminophores from layers 155, 160, and 165 into a single isotropic layer. The same absorption-emission cascade would still occur between the luminophores, it would just occur in a single layer. The oriented luminophore layer 170 would still be separate, in this exemplary embodiment.

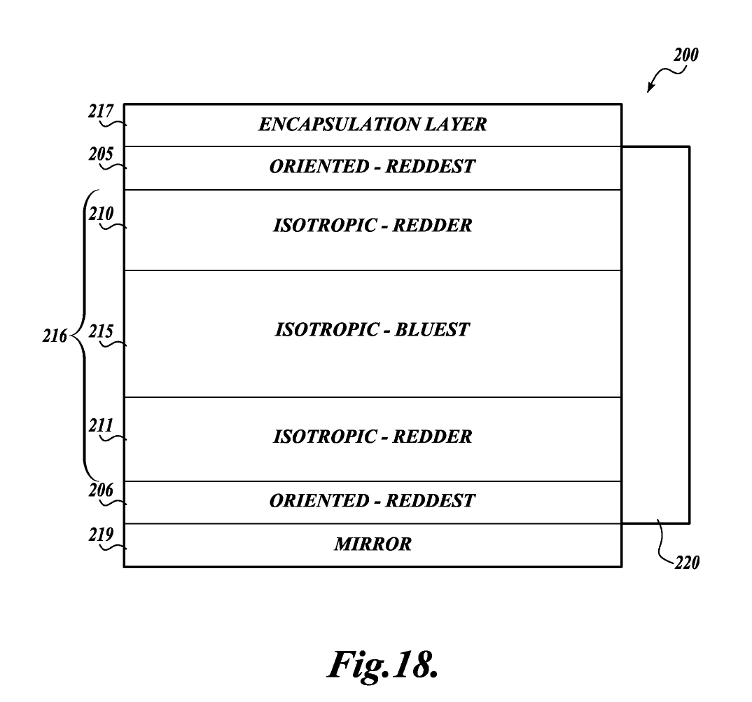

Referring now to FIG. 18, a “packaged” LSC device 200 is illustrated wherein a number of isotropic layers 210, 211, and 215 form a core 216 comprising only isotropic luminescent layers. The core 216 is bounded on the upper and lower ends by oriented reddest layers 205 and 206.

The bottom layer of the device is a mirror 219 configured to reflect at least the reddest wavelength. In a preferred embodiment, the mirror 219 reflects all wavelengths that may potentially impinge on the mirror 219.

In an alternative embodiment, mirror 219 can be either a mirror or a scattering surface.

In an exemplary device design, the mirror 219 is preferably separated from layer 206 by either an air gap or a low-index layer (not illustrated). Direct contact with layer 206 would likely diminish the TIR efficiency of the waveguiding in layer 206.

The top layer of the device is an encapsulation layer 217, which can serve to protect the device 200 from environmental conditions, such as moisture, oxygen, and other damaging effects. The encapsulation layer 217 may also be an anti-reflection layer that is configured to allow maximum light impinging on the device 200 into the luminophores contained within. The luminophore-containing layers 205, 206, and 216 all abut a photovoltaic cell 220 for converting light emitted into electrical current.

In the device 200 illustrated in FIG. 18, the bluest layer 215 is in the middle of the device, followed by, moving outward, isotropic redder layers 210 and 211, and finally, bounded by oriented reddest layers 205 and 206. It will be appreciated that the similarly named, but differently numbered components of the device 200 can be either the same or different. That is, the isotropic redder layers 210 and 211 can be the same or different, as can the oriented reddest layers 205 and 206, etc.

As discussed above with regard to FIG. 17, the oriented reddest layer 170 in the device 150 acts to create a boundary for the light contained within the device 150 so as to maximize containment of the energy harvested by the device 150 and turned into electrical current by the photovoltaic cell 175. This concept is extended in the device 200 illustrated in FIG. 18, wherein oriented reddest layers 205 and 206 bound both the top and bottom of the device 200 so as to create confinement at both upper and lower surfaces of the device 200, thereby maximizing the amount of light energy retained within the device.

In certain embodiments, the luminophore layer with the longest emission wavelength (e.g., the “reddest”) includes oriented luminophores.

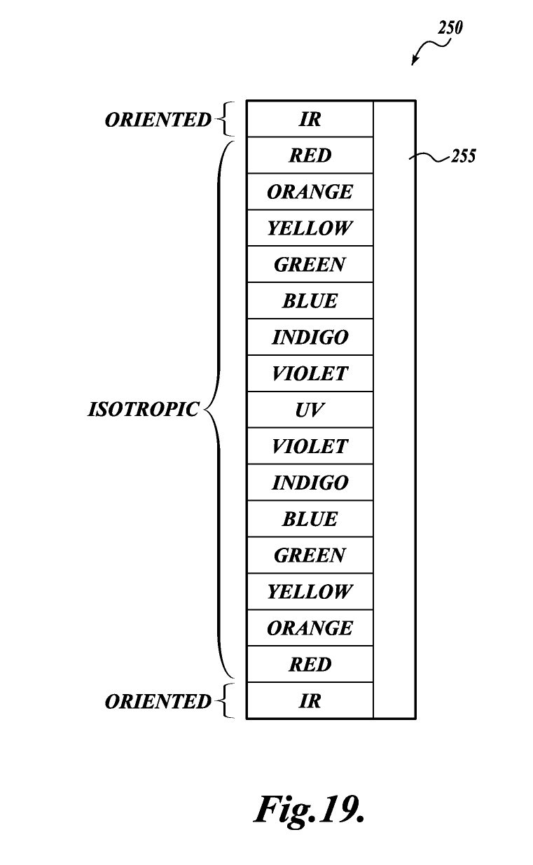

FIG. 19 illustrates the potential scope and complexity of representative MLLSC of the invention. The MLLSC 250 illustrated includes a relatively large number of isotropic luminophore waveguide layers (labeled according to the color of luminescent emission) symmetric about the ultraviolet (UV) waveguide so as to provide the emission-absorption cascade described with reference to FIG. 17. The isotropic waveguide stack is bordered at the top and bottom by oriented infrared (IR) luminophores in a waveguide (e.g., similar to FIG. 18). The waveguides each luminesce and a PV cell 255 collects any incident light.

Fabrication of MLLSCs is accomplished using methods known to those of skill in the art and disclosed herein. For example, oriented luminophore layers can be fabricated using LC, extrusion, or other methods disclosed herein. Isotropic layers can be fabricated using known methods (e.g., spin coating, drop coating, evaporation, vapor deposition, and the like).

A substrate may be used to support a layer (or layers) that are not self supporting. For example, a substrate may be used to spin coat a guest host system to be aligned to provide an aligned-luminophore layer of a MLLSC. After the alignment is performed, isotropic, or additional aligned layers of the MLLSC can be deposited sequentially. Alternatively, the MLLSC can be fabricated in two or more portions and joined (e.g., bonded) to form a finished device. The “stack” of luminophore-containing waveguides is edge-coupled to a PV cell to form a completed MLLSC system for producing electricity.

Representative fabrication methods for MLLSCs are described further below in the EXAMPLES section.

In one aspect, a luminescent solar concentrator is provided. In one embodiment, the LSC comprises a plurality of waveguides,

said plurality of waveguides comprising at least one first isotropic waveguide and at least one first oriented waveguide,

said first isotropic waveguide comprising an isotropic plurality of first luminophores, each having a first absorption wavelength and a first emission wavelength,

said first oriented waveguide comprising an oriented plurality of second luminophores, each having a second absorption wavelength and a second emission wavelength.

In one embodiment, the second emission wavelength is longer than the first emission wavelength.

In one embodiment, the first oriented waveguide is in optical communication with the first isotropic waveguide.

In one embodiment, the first isotropic waveguide further comprises an isotropic plurality of third luminophores, said third luminophore each having a third absorption wavelength and a third emission wavelength.

In one embodiment, the luminescent solar concentrator further comprises a third waveguide in optical communication with at least one of the first isotropic waveguide and the first oriented waveguide, wherein the third waveguide is selected from the group consisting of an oriented waveguide comprising an oriented plurality of third luminophores, and an isotropic waveguide comprising an isotropic plurality of the third luminophores, said third luminophore each having a third absorption wavelength and a third emission wavelength.

In one embodiment, the third waveguide is intermediate the first isotropic waveguide and the first oriented waveguide, and wherein the third emission wavelength is intermediate the first emission wavelength and the second emission wavelength.

In one embodiment, the first luminophore has an emission wavelength of from 350 nm to 400 nm.

In one embodiment, the second luminophore has an emission wavelength of from 500 nm to 700 nm.

In one embodiment, the first emission wavelength overlaps with the second absorption wavelength.

In one embodiment, the first isotropic waveguide further comprises a plurality of third luminophores each having a third absorption wavelength and a third emission wavelength, wherein the third luminophores are selected from the group consisting of isotropic and oriented.

In one embodiment, the oriented plurality of second luminophores are aligned along a director axis selected from the group consisting of a long molecular axis of each luminophore; an absorption dipole of each luminophore; and an emission dipole of each luminophore.

In one embodiment, the oriented plurality of second luminophores are oriented with regard to their emission dipole at a first angle in relation to a major surface of the first oriented waveguide.

In one embodiment, the first angle is from 45 to 90 degrees.

In one embodiment, the oriented plurality of second luminophores are oriented with regard to their absorption dipole at a second angle in relation to a major surface of the first oriented waveguide.

In one embodiment, the second angle is from 0 to 90 degrees.

In one embodiment, the LSC comprises a core waveguide comprising the first isotropic waveguide.

In one embodiment, the core waveguide comprises the third waveguide.

In one embodiment, the core waveguide and the first oriented waveguide are planar waveguides arranged in a stack.

In one embodiment, the core waveguide has a thickness that is at least twice a thickness of the first oriented waveguide.

In one embodiment, the LSC further comprises a second oriented waveguide comprising an oriented plurality of fourth luminophores, each having a fourth absorption wavelength and a fourth emission wavelength, wherein the second oriented waveguide is in optical communication with the core waveguide, and wherein the core is intermediate the first oriented waveguide and the second oriented waveguide.

In one embodiment, the fourth luminophores are the same as the second luminophores.

In one embodiment, the LSC further comprises a mirror adjacent the first oriented waveguide, wherein the first oriented waveguide is intermediate the core and the mirror, and wherein the mirror is configured to reflect light of the second absorption wavelength.

In one embodiment, the LSC further comprises a scattering film abutting the first oriented waveguide, wherein the first oriented waveguide is intermediate the core and the scattering film.

In one embodiment, the LSC further comprises an anti-reflective layer configured to reduce reflections of incident light from the upper surface, allowing more light to enter the device, wherein the core is intermediate the anti-reflective layer and the first oriented waveguide.

In one embodiment, the LSC further comprises a collector waveguide of a TW-LSC, so as to form a MLLSC collector of a TW-LSC device.

In one embodiment, the LSC further comprises a photovoltaic device in optical communication with the edge surface.

In one embodiment, the luminophores comprise mesogens.

In one embodiment, the mesogens are polymerizable mesogens.

In one embodiment, the luminophore comprises a plurality of aligned luminophores.

### Tandem-Waveguide Luminescent Concentrators

In another aspect, the invention provides tandem-waveguide LSCs (TWLSCs) that include a collector waveguide in optical communication with a transport waveguide. The collector waveguide acts as a traditional LSC in that it includes luminophores and directs luminesced light. The collector waveguide terminates (at least at one end) at the transport waveguide, which provides a low-absorption waveguide in relation to the collector waveguide. Typically, the transport waveguide does not contain luminophores. In a single TWLSC, multiple collector waveguides can be arranged around a single transport waveguide.

The luminophores in the collector waveguide are preferably aligned according to the OLSC and MLLSC devices described herein.

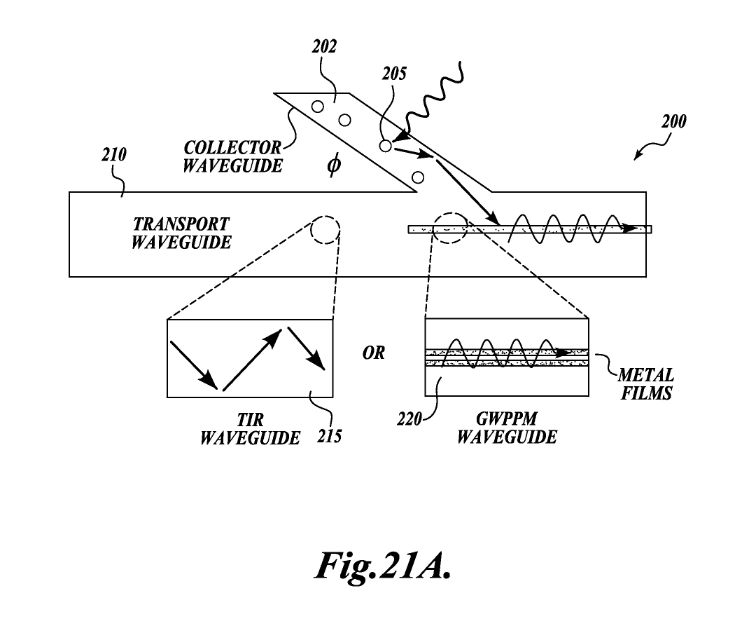

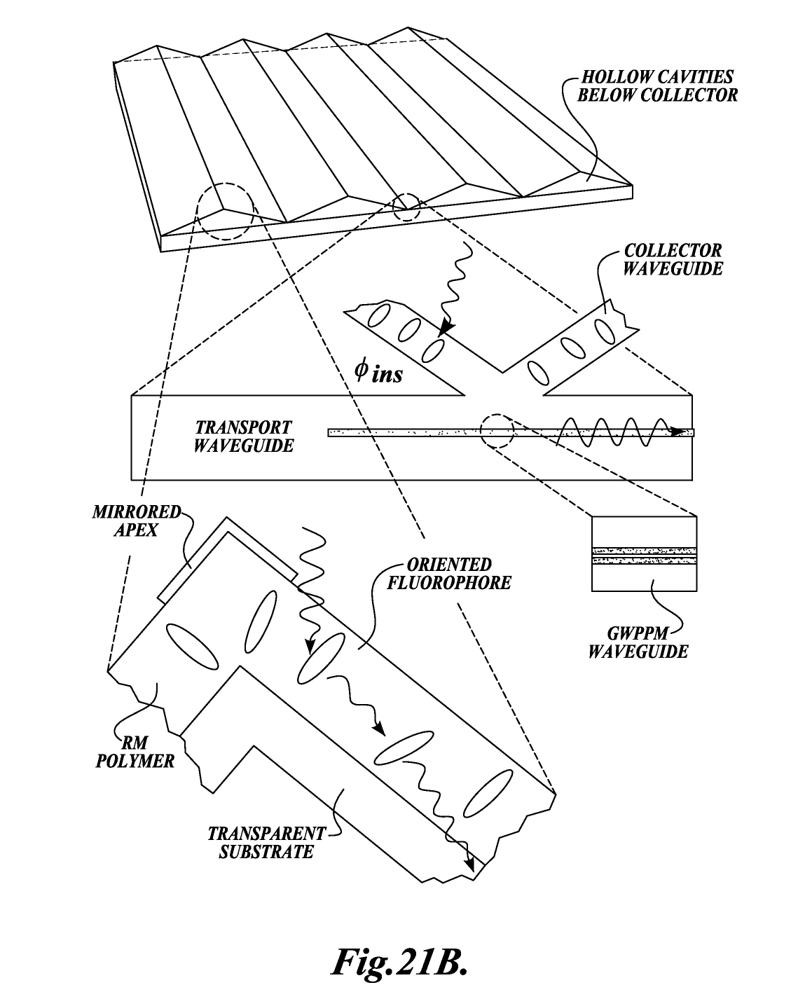

One embodiment of a TW-LSC is illustrated in FIG. 21A. The TW-LSC 200 consists of two components: a set of multiple, small “collector” waveguides 202, impregnated with fluorophores 205; and a “transport” waveguide 210 for carrying light to the edges of the concentrator 200 (e.g., to a PV cell). The concentrator 200 can be either planar (i.e., both the collector and transport waveguides are in the same plane as in FIG. 21A) or stacked such that the collector is intermediate a light source and the transport waveguide (as in FIG. 21B). Multiple collector waveguides 202 can be interfaced with a single transport waveguide 210, so as to cover a relatively large total concentrator area into mm- to cm-sized collectors. Using a TW-LSC 200, the collection of photons is separated from the function of transporting photons. By separating the collection and transportation functions, different materials can be used for the collector and transport waveguides, each having specific properties that optimize the efficiency of the device.

For example, by using separately optimized materials, the optical path length of fluorescent light in the collector waveguides can be reduced by an order of magnitude for a 1 m² concentrator. This dramatically reduces self-absorption losses, which increase roughly exponentially with optical path length. A more efficient device results.

TW-LSCs couple light from the collector waveguides 202 into a low loss transport waveguide 210 for delivery to the edges of the concentrator 200. The simplest way to accomplish this is to use a transparent plate 215 whose refractive index matches the collector waveguides, thereby confining light by total internal reflection (TIR) if the entry angle φ (e.g., the angle at which the collector intersects the transport waveguide in FIG. 21A) is below the critical angle. The angle at which the collector intersects with the transport will define the angle at which light from the collector intersects with the transport only if the luminophores within the collector are oriented so as to emit light in the plane of the collector. This condition is important for device efficiency, because escape optical loss will result in both the collector and at the junction of the collector and transport, if the collector light is not properly directed.

Preliminary calculations (see below) indicate TIR transport waveguides will have losses of ˜0.25-1.0 dB m⁻¹ for reasonable geometries due to scattering from collector-transport waveguide junctions, leading to peak optical collection efficiencies Q=(No. of photons emitted from the LSC edge)/(No. of absorbed solar photons) that are 2-5 times greater than conventional planar LS Cs, and peak energy concentrations Cₑ>10 times greater. Achieving these performance metrics enables significant cost reductions in collectors of a size suitable for rooftop applications matched to ordinary efficiency PVs.

In certain embodiments, TW-LSC with losses in the transport waveguide below ˜0.1 dB m⁻¹ are provided, enabling very large, high efficiency collectors with high efficiency PVs for utility-scale applications. In these embodiments, guided-wave plasmon-polariton modes (GWPPM) are used in the transport waveguide 220 of the TW-LSC 200. GWPPMs are a type of surface-constructed wave occurring in metal-dielectric-metal thin film structures. Unlike ordinary surface plasmon polaritons, most of the electric field amplitude in a GWPPM is localized to the dielectric layer, and coupling of light into the structure is unidirectional. As a result of these unusual properties, GWPPM waveguides offer ultralow insertion and transport losses.

Referring now to FIG. 21B, an alternative TW-LSC design is illustrated. The TW-LSC of FIG. 21B is similar to that of FIG. 21A, although the collector wave guides are configured so as to be intermediate the light source and the transport wave guide. In the representative configuation illustrated in FIG. 21B, the collector wave guides are tented such that there are hollow cavities below the collector wave guides and a plurality of apexes and troughs so as to provide a structure whereby the upward faces of the collector wave guides can accept light from a light source. Upon impinging of light from a light source, oriented fluorophores embedded in the collector wave guides preferentially emit fluoresced light in the plane of the collector wave guide. At the trough between downward-slanting collector wave guides, the light collected by the collector wave guide is delivered to the transport wave guide for efficient transport to the edges of the device (e.g., to a PV cell). The transport wave guide can be either a traditional total internal reflection wave guide, or can operate using the GWPPM wave guides described elsewhere herein.

In conventional LSCs minimization of fluorophore self-absorption is normally the single most important design goal. For TW-LSCs on the other hand, the focus shifts to include other factors, some that are shared by conventional LSCs, and some that are new. For example, collector waveguide geometry, integration with the transport waveguide, and fluorophore characteristics such as spectral coverage, quantum efficiency, and PV bandgap matching now become more important than minimizing self-absorption.

In a preferred embodiment, the luminophores of the collector waveguide are oriented (e.g., oriented as in OLSCs described herein). Oriented luminophores in the collector waveguide reduce light lost from both the collector and transport waveguides. This is true even if the angle phi in FIG. 21A is very shallow.

As discussed below, all exemplary collector waveguides and TIR transport waveguides are fabricated from polymethylmethacrylate (PMMA). GWPPM transport waveguides are constructed on Si and glass, also discussed below. Small PMMA waveguides are formed by injection molding and larger ones by compression thermoforming. Collector waveguides are bonded to transport waveguides with index-matching adhesive, with mirrored edges created by metallization or application of adhesive mirror film.

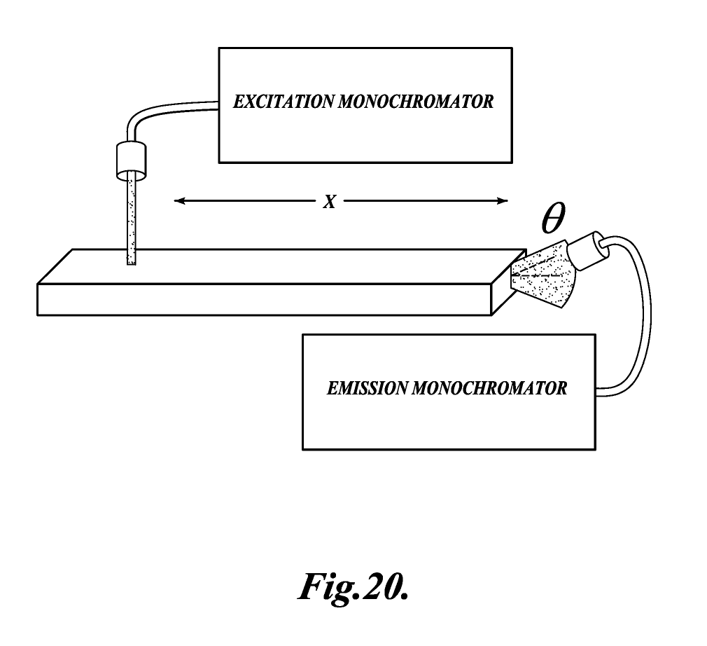

Spectroscopic and photon flow measurements can be performed using the apparatus in FIG. 20. It consists of a custom fluorescence spectrometer enabling illumination and collection from separate locations on samples up to 1 m² in size. Three types of illumination sources are employed: (i) a monochromator for spectral measurements; (ii) a small-spot solar simulator; and (iii) a large area (up to 12″ diameter) solar simulator. Spot size and beam characteristics are selected with interchangeable masks and filters to provide diffuse or specular illumination and varying intensity. Light is collected from a spot at the edge of the concentrator with remaining areas masked by black paint. The system is calibrated using reference fluorophores to enable measurements of absolute efficiency Q and concentration ratio, Cₑ.

Measurements on collector waveguide building blocks, full collector waveguides, and integrated concentrators provide fundamental parameters needed as inputs for modeling, including loss rates associated each optical process in the system.

The issues related to fluorophore selection and performance in TW-LSCs are basically the same ones as those for conventional LSCs, but with a different order of importance because self-absorption losses are greatly reduced with TW-LSCs. The main criteria are lifetime, quantum efficiency, and spectral coverage.

With regard to lifetime, for LSCs to provide a 20 year lifetime, fluorophore photodegradation rates can be no higher than ˜10⁻⁸ per absorbed photon. Although dyes used in early work lacked sufficient stability, in recent years a wide range of commercially available fluorophores has been developed for fluorescent imaging, organic light emitting diode, and laser dye applications that meet this requirement.

With regard to quantum efficiency, fluorescence quantum yield (QY) affects both the efficiency of capturing primary solar photons and the loss rate from self-absorption. Although important for the first reason, QY requirements for TW-LSCs are somewhat less stringent than for conventional LSCs because of reduced self-absorption. Preferred luminophores include fluorophores with QY>0.7, which includes dozens of commercially available organic dyes, and semiconductor quantum dots (QD).

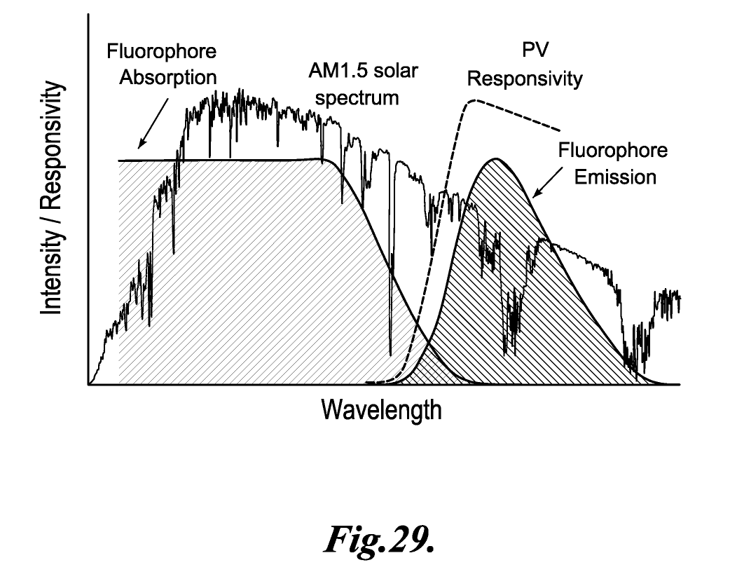

With regard to spectral coverage and photovoltaic bandgap matching, to illustrate some key issues, the properties of a hypothetical “ideal” fluorophore are illustrated in FIG. 29. The ideal fluorophore absorbs over a broad region of the solar spectrum and has a narrow emission peak just above the bandgap of the PV cell and near its peak responsivity. In practice, because no single fluorophore is simultaneously able to meet this and the other requirements, fluorophores covering a narrower spectral region are used instead. In principle, a stack of LSCs (e.g., FIG. 17), each harvesting a different spectral region and matched to a different type of PV can be used. This approach offers the highest theoretical efficiency.

By using three or four fluorophores in which the emission from one member of the series is absorbed and re-emitted by the next, essentially the entire near-UV and visible spectrum can be covered, with emission determined by the terminal dye. For example, the Lumogen series of dyes from BASF: Violet570→Yellow083→Orange240→Red300 provides nearly complete coverage over the range 300-580 nm with terminal emission at 620 nm. The QY of these dyes is, respectively, 0.94, 0.99, 1.0, and 0.98, for an overall QY=0.91. A similar strategy based on fluorescence resonance energy transfer (FRET) is also possible.

Self-absorption of fluorescent emission, while less important in a TW-LSC than in a conventional LSC, still plays a role and must be considered to some extent. To understand the important issues, the self-absorption ratio S=the ratio of absorption coefficients at the absorption and emission maxima, provides a useful estimation of self-absorption losses for a given fluorophore. Fluorophore concentration and geometric gain G (where G=edge area/facial area) are connected through the extinction coefficient and S, since a large fraction of solar photons is desirable, but a small fraction of fluoresced photons should be absorbed. A design rule of thumb for conventional LSCs is G≦˜2 S for high efficiency operation and the limiting energy concentration Cₑ is reached at roughly G ˜10 S. Conventional LSCs therefore require S≧10²-10³ to achieve useful concentrations, and the lack of stable fluorophores with such large implied Stokes shifts is the main reason LSC research was essentially abandoned in the 1980's. In contrast, because each collector waveguide in a TW-LSC is comparatively small, they can tolerate much smaller values while achieving useful concentrations, even S<10. Thus a whole range of fluorophores that would have far too much self-absorption to be useful in a conventional LSC, can be used in a TW-LSC.

Initial studies include well-characterized and understood fluorophores such as 4-(Dicyanomethylene)-2-methyl-6-(4-dimethylaminostyryl)-4H-pyran (DCM) and members of the rhodamine, perylene, merocyanine, and coumarin families of dyes.

Additional fluorophores, such as the Lumogen family from BASF, which were specifically formulated in part for stability and solubility in PMMA, and newer laser and OLED dyes such those from Excition are also useful. Finally, less conventional fluorophores, including cascaded fluorophore series and semiconductor QDs can be used. The latter have some advantages in terms of spectral coverage, PV bandgap matching, and the potential for multiexciton fluorescence. Optical properties of a number of fluorophores described herein are provided in Table 1.

TABLE 1
Summary properties of representative fluorophores discussed in the text

| | Self- | | | | | |
|---|---|---|---|---|---|---|
| | absorption | Absorbance | | Fluorescence | | |
| Fluorophore | S | λₘₐₓ^{abs} (nm) | ∈ₘₐₓ^{abs} 10⁵ | λₘₐₓ^{em} (nm) | QY | Core |
| DCM | 14 | 465 | 2.9 | 636 | 0.81 | |
| Rhodamine | 5-7 | 520-540 | 10-12 | 550-565 | >0.95 | xanthene |
| family | | | | | | |
| Lumogen family | 5-10 | 380-600 | ~5 | 430-610 | >0.94 | perylene |
| Coumarin family | 7-9 | 450-500 | 5-7 | 500-520 | 0.8-0.9 | coumarin |
| BODIPY family | 5-10 | 490-650 | 8-11 | 520-700 | 0.92-0.99 | dipyrromethane |
| semiconductor | 1.2-3 | 500-800 | 10-12 | 500-800 | 0.5-0.8 | |
| QDs | | | | | | |

In one aspect, a luminescent solar concentrator is provided. In one embodiment, the LSC comprises:
(a) a collector waveguide comprising a luminophore having an emission wavelength, and a first surface configured to receive electromagnetic radiation, wherein the collector waveguide has a first optical loss at the emission wavelength; and
(b) a transport waveguide comprising a transport material in optical communication with a portion of the collector waveguide and at least one edge surface through which electromagnetic radiation can escape, wherein the transport waveguide has a second optical loss at the emission wavelength, and wherein the second optical loss is less than the first optical loss.

In one embodiment, the luminescent solar concentrator of claim 1 further comprises a photovoltaic device in optical communication with the edge surface of the transport waveguide through which electromagnetic radiation can escape.

In one embodiment, the transport waveguide abuts a second surface of the collector waveguide.

In one embodiment, the transport waveguide abuts an edge surface of the collector waveguide.

In one embodiment, the collector waveguide and the transport waveguide are both planar waveguides, and wherein the collector waveguide intersects a major planar surface of the transport waveguide at an angle.

In one embodiment, the collector waveguide comprises a host material incorporating the luminophore as a guest.

In one embodiment, the transport material is the same as the host material.

In one embodiment, the transport material is a guided-wave plasmon-polariton mode material. In a further embodiment, the guided-wave plasmon-polariton mode material comprises a series of layers: a first dielectric layer abutting the collector waveguide, a first metal layer abutting the first dielectric layer, a core dielectric layer abutting the first metal layer, a second metal layer abutting the core dielectric, and a second dielectric layer abutting the second metal layer. In another embodiment, the collector waveguide comprises a longitudinal axis that intersects the transport waveguide at a first angle. In a related embodiment, the first angle provides unidirectional insertion of light at the emission wavelength from the collector waveguide into the guided-wave plasmon-polariton mode material.

In one embodiment, the optical loss of the transport material at the emission wavelength is less than 1 dB/m.

In one embodiment, the luminophore has an absorption peak wavelength in an electromagnetic spectrum selected from the group consisting of infrared, visible, and ultraviolet.

In one embodiment, the emission wavelength is in an electromagnetic spectrum selected from the group consisting of infrared, visible, and ultraviolet.

### Theory

Oriented LSC Theory

The disclosed embodiments improve LSC performance through orientationally engineered polymer waveguides. The basic concept is illustrated in FIG. 2. A fluorescent dye or system of dyes is incorporated into a liquid crystal (LC) made from “reactive mesogens” (RMs, extruded polymers, or stretched polymers), which are small-molecule liquid crystalline monomers that can be photopolymerized to “lock in” orientational order. For example, films are applied as a thin layer on a glass substrate with matching refractive index. The fluorophore is made to orient along a chosen axis within the material through a combination of (i) control over the orientation of the RM director n̅, and (ii) suitable chemical modification of the dye. The preferred arrangement in most instances places the transition dipole μ̅ₑ associated with the S₁→S₀ emission perpendicular to the plane of the film (“homeotropic alignment”), so that emission occurs preferentially in the plane of the LSC waveguide (FIG. 3). This is advantageous for several reasons discussed below. The transition dipole μ̅ₐ associated with absorption S₁←S₀ then makes an average angle β with n, which for the exemplary perylene dyes is nearly constant over the entire visible spectrum.

Optically oriented fluorescent waveguides behave in some unique ways compared to their isotropic counterparts, with particular advantages and disadvantages depending on the degree and type of orientational order. We quantify orientational order for any particular axis (n, μₑ, or μₐ,) through the first non-zero moment of its orientational distribution function (ODF), expanded in terms of Legendre polynomials and expressed using the order parameter [symbol] P₂ (cos α) [symbol] = [symbol] 3/2 cos² α−½ [symbol] , and in some cases a second order parameter,

$$〈 {P}_{4} ( cos α ) 〉 = \frac{1}{35} 〈 35 {cos}^{4} α - 30 {cos}^{2} α + 3 〉 .$$

Here, [symbol] denotes an average over the entire sample. For simplicity we assume the dye has uniaxial symmetry, although more general treatments are also available. Both P₂ and P₄ can be determined by suitable spectroscopic measurements described below,¹⁴ and from them one can reconstruct an estimate of the full ODF of μ̅ₑ , and μ̅ₐ with respect to the symmetry axis n̅.

To understand how the order parameters and β are related to optical properties and how orientational control can be used to improve performance, let us consider first the ideal case, followed by what can be reasonably achieved in practice. The ideal material, sketched in FIG. 4, would be homeotropically aligned with P₂( μ̅ₑ)˜1 and β˜90°. With this combination, photons emitted from fluorescent dyes would be entirely confined within the LSC plane and polarized perpendicular to μ̅ₐ. Consequently, (1−ηₜᵣₐₚ)=100% and light could not escape the waveguide, no matter how many re-absorption/re-emission events occurred. Furthermore, since β=90° in the ideal material one fluorophore could not absorb the emission of another, even for a dye with strongly overlapping emission and absorption bands, since the absorbance depends on μ̅ₐ· μ̅ₑ=0. Finally, μ̅ₐ is optimally situated in the plane of the LSC to capture sunlight, enabling a lower concentration of dye to be used (by a factor ˜2 to achieve the same absorbance as the equivalent isotropic material).

If a material with these ideal parameters could be prepared, it would essentially eliminate the main origins of transport loss, from both escape-cone emission and self-absorption followed by non-radiative decay.

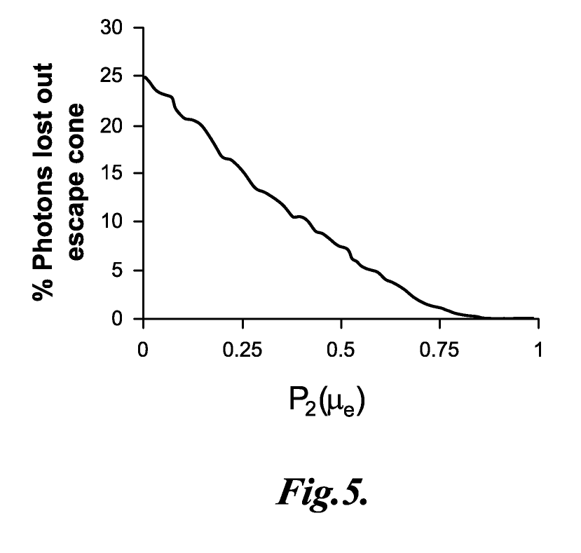

The first parameter, homeotropic orientation of the LC director, can be readily achieved in several ways as discussed below. The second parameter, P₂( μ̅ₑ)˜1 is unrealistically large, but values fairly close to this, in the range P₂=0.7˜0.8 are possible, and have been reported for literally hundreds of dyes in dozens of LC hosts and mechanically stretched polymer systems. Based on preliminary results from ballistic photon Monte Carlo simulations (see EXAMPLES), the majority of benefits from alignment have already been achieved when the order parameter P₂( μ̅ₑ)˜0.8. For example, FIG. 5 shows that the fraction of photons emitted at angles that would trap them within a waveguide with a refractive index n=1.5 is over 99.6% for P₂( μ̅ₑ)=0.8. However, this is true if there is a considerable beta. If beta is close to zero (e.g., less than 15 degrees) then optimal alignment is about 0.7; for moderate beta (e.g., 15 to 30 degrees) then optimal alignment is 0.75-0.8.

It is the third parameter, β˜90°, that poses the greatest challenge. For the overwhelming majority of strongly photoluminescent organic dyes, β≦30°, as can be understood on the basis of the Franck-Condon principle. Furthermore, although fluorescent dyes with small β are specifically sought for applications such as fluorescence polarization decay probes, there appears to have been little prior interest in finding or developing dyes with large β. For the unmodified perylene core used in the experiments below, β˜10°-20°, and for the coumarin dye used in preliminary devices, β=31°. This has two consequences: First, self-absorption is actually higher than the corresponding isotropic material due to the approximate colinearity of μ̅ₐ and μ̅_{b} . More generally, it is not difficult to show that for β<54° self-absorption is stronger in an oriented sample than an isotropic one, at β=54° it is the same, and for β>54° self-absorption is reduced. Second, absorption of sunlight is weaker than the corresponding isotropic material due to the unfavorable orientation of μ̅ₐ, requiring a higher dye concentration to achieve the same effective absorption.

As a result of these competing factors, predicting and understanding the performance impacts from orientation becomes a complicated problem, dependent on a number of interrelated variables. We have examined a certain number of cases through preliminary Monte Carlo simulations as well as the construction and characterization of several devices, summarized in the following section. The results show that even for dyes with small β, the efficiency of oriented fluorescent waveguides should be 50%-100% higher than their isotropic counterparts. Even greater gains are possible using new fluorophore concepts below that take advantage of alignment, as well as new LSC architectures exploiting oriented materials' characteristic collimated edge emission.

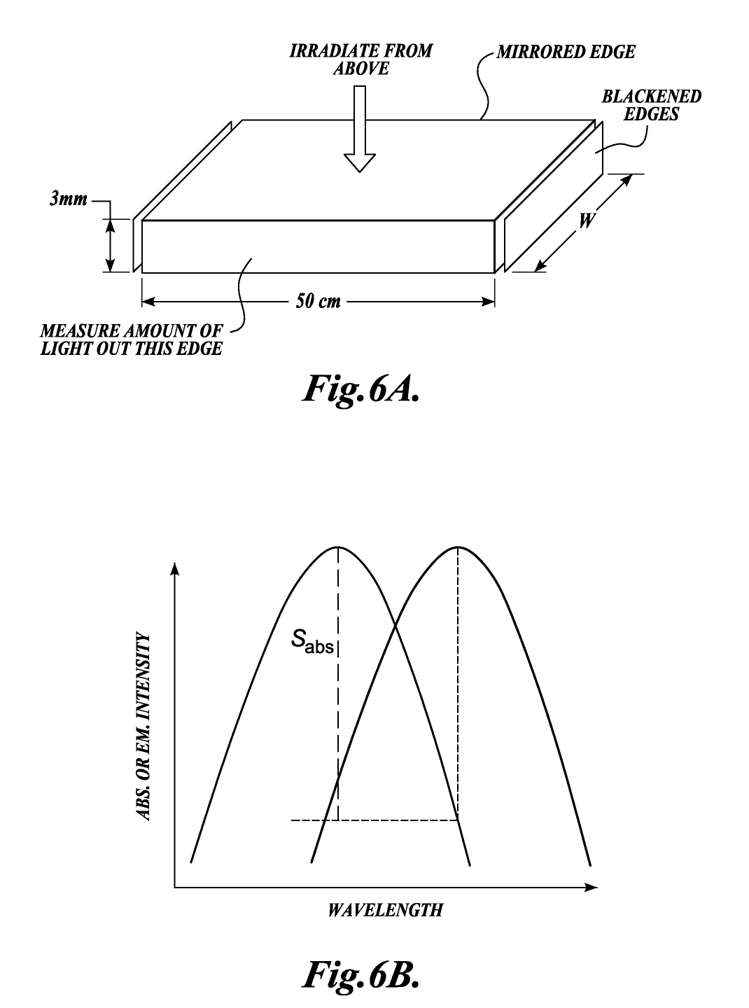

Monte Carlo Simulations. We conducted preliminary simulations of photon transport modeling a slab of an optically oriented fluorescent waveguide subjected to uniform illumination from above (FIG. 6A). We wish to determine the expected percent of light that makes it out the front edge, expressed as the optical quantum efficiency (OQE) relative to the OQE of a similar isotropic waveguide. A brief summary of the model follows:

Fluorophore absorption and emission spectra were modeled very simply in these preliminary simulations, as two Gaussian distributions of equal width with peaks partially offset to allow some self-absorption to occur (FIG. 6B). We use a self-absorption parameter: S_{abs}=(fluorophore absorbance at the peak absorbance wavelength)/(fluorophore absorbance at the peak emission wavelength), to express the degree of overlap between absorption and emission bands, and hence how strongly the fluorophore self-absorbs. Values were investigated from 10<S_{abs}<500, covering essentially the entire range of known fluorophores. The principal parameters explored in our preliminary simulations were: S_{abs}, P₂( μ̅ₑ), β, and the width of the slab, W. Photoluminescent quantum yield η_{φ} and fluorophore concentration also strongly affect a given material's performance The former was set equal to η_{φ}=0.95 for all simulations. To minimize the effect of the latter and focus more clearly on the roles of orientation and β, multiple simulations were performed for each parameter set {S_{abs}, P₂( μ̅ₑ), β, W} in order to first determine the optimum concentration C* for that set. C* was then used in simulations to measure the OQE. Thus the results presented below compare the OQEs of various oriented materials to the corresponding “best case” isotropic material.

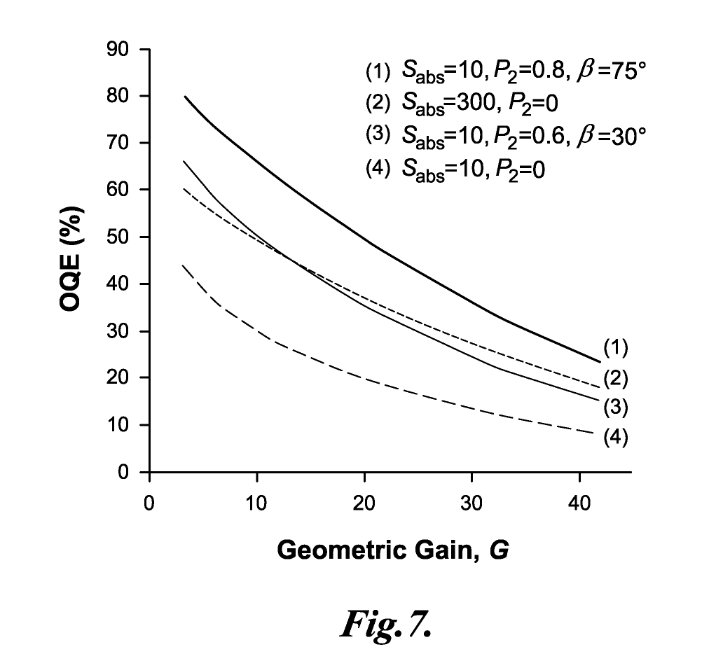

FIG. 7 illustrates the results of Monte Carlo simulations comparing the performance of two oriented systems (solid lines) to two isotropic materials (dashed). (1) oriented waveguide with very favorable orientational parameters, but typical S_{abs}; (2) isotropic waveguide with self-absorption S_{abs} close to the best LSC fluorophore yet discovered; (3) oriented system with parameters comparable to a typical organic guest fluorophore dissolved in a LC host; (4) isotropic waveguide with S_{abs} for a typical organic dye.

The Monte-Carlo simulation takes into account the alignment statistics of the emission dipoles, the initial lack of polarization of the incoming photon, and the statistics of the polarization of emitted photons. This occurs in the determination of the “transport length” of a given photon, which is the expected distance a photon will travel before it is absorbed. We rigorously derive the statistics for transport length for randomly polarized photons, which depend on the statistics of fluorophore alignment, β, concentration, photon energy, and direction of photon travel, \vec{ν}. We also derive the statistics of transport length for emitted photons whose polarization vectors carry the statistics of the alignment of the emission dipoles. An emitted photon propagates with a sampled direction \vec{ν}; if it encounters the top or bottom of the slab, it is either reflected or lost according to the escape cone determined by the difference in refractive indices of the slab to the air, taking into account the Fresnel relations. The photon continues to propagate, reflecting as necessary until it is either lost out the top, bottom, or one of the blackened sides, emitted from the front edge, or exhausts its sampled transport length. In this latter case, the photon is absorbed by a new sampled molecule and the just-described process repeats. This is repeated for tens to hundreds of thousands of photons.

The main results from these preliminary simulations are summarized in FIG. 7, which compares the OQEs of two oriented materials to an isotropic waveguide with S_{abs}=10, which is representative of an ordinary organic fluorophore, such as fluorescein, and S_{abs}=300, which is comparable to the best performing LSC fluorophores yet reported. The data are plotted vs. geometric gain, G=(slab facial area)/(slab edge area) in order to allow direct comparison to the OQE's of known LSC materials.

As shown by comparing (3) and (2) lines in FIG. 7, a perfectly ordinary fluorescent dye, with η_{φ}=0.95, and S_{abs}=10 and β=30° performs comparably to the best performing LSC materials known to the inventors, even if it is only moderately well ordered (P₂=0.6).

Increasing β or P₂( μ̅ₑ) improves performance Although the data are not shown, increasing η_{φ} is similarly beneficial.

The results of simulations and preliminary experiments (described in the EXAMPLES) show that light from the LSC edges is partially collimated with an angular distribution function related to P₂( μ̅ₑ). This is a new characteristic resulting from fluorophore orientation, not exhibited by isotropic materials. It is significant because collimated emission may enable more efficient coupling to PV cells, as well as new LSC architectures that further improve efficiency through novel designs. As an example, collimated emission could be used to efficiently inject light from numerous small fluorescent “collector” waveguides and into an optically clear “transport” waveguide, as in the TW-LSC devices provided herein. By separating light harvesting and light transport functions, such a design could reduce self-absorption-related losses even further. This has not been possible with isotropic LSC materials, where photons are emitted from the edge at all angles.

GWPPM Theory

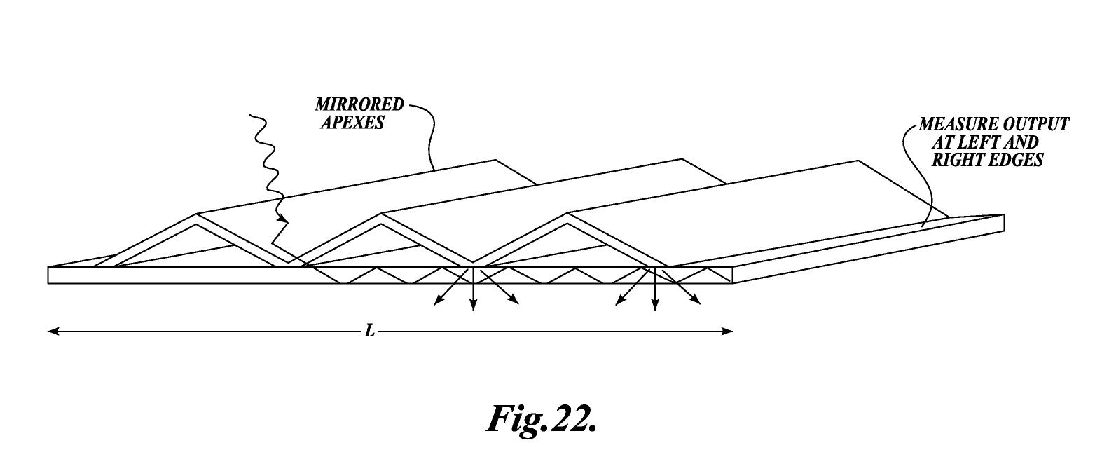

To illustrate the theory behind GWPPM waveguides, we consider the TW-LSC shown in FIGS. 21B and 22. The concentrator is an infinitely long strip of width L, divided into A-shaped collector waveguides, each having mirrors at the apexes. Emission is collected from the left and right edges of a TIR transport waveguide. We assume that losses in the transport waveguide are dominated by scattering from collector-transport waveguide junctions, with 100% loss of all light in the collector waveguide that encounters one of these junctions. This is approximately the loss rate we measured in non-optimized prototype TW-LSCs having the architecture of FIG. 21 made from thermoformed acrylic doped with 10⁻⁴ M of the classic laser dye 4-(Dicyanomethylene)-2-methyl-6-(4-dimethylaminostyryl)-4H-pyran (DCM). If each collector fin has a geometric gain G₁=(collector fin facial area)/(collector fin edge area), for a large concentrator the maximum number of photons emitted at the edges will be: Nₒᵤₜ≈∈ᵢₙₛₑᵣₜN₁/(1−(1−1/2G₁))=2∈ᵢₙₛₑᵣₜG₁N₁, where N₁ is the number of photons an individual collector fin injects into the transport waveguide and ∈ᵢₙₛₑᵣₜ is the insertion efficiency (∈ᵢₙₛₑᵣₜ is nearly 1 for a TIR transport waveguide with a small entry angle, φ). Work on conventional LSCs in the 1970's and 1980's led to the development of devices with G₁=2-20 and typical energy concentration factors C_{c}=2-5. Thus we may conservatively estimate that large (≧0.5 m²) TW-LSCs based on TIR transport waveguides should be able to achieve at least 10-fold increase in concentration over conventional LSCs of the same size, or 20-50 suns of intensity.

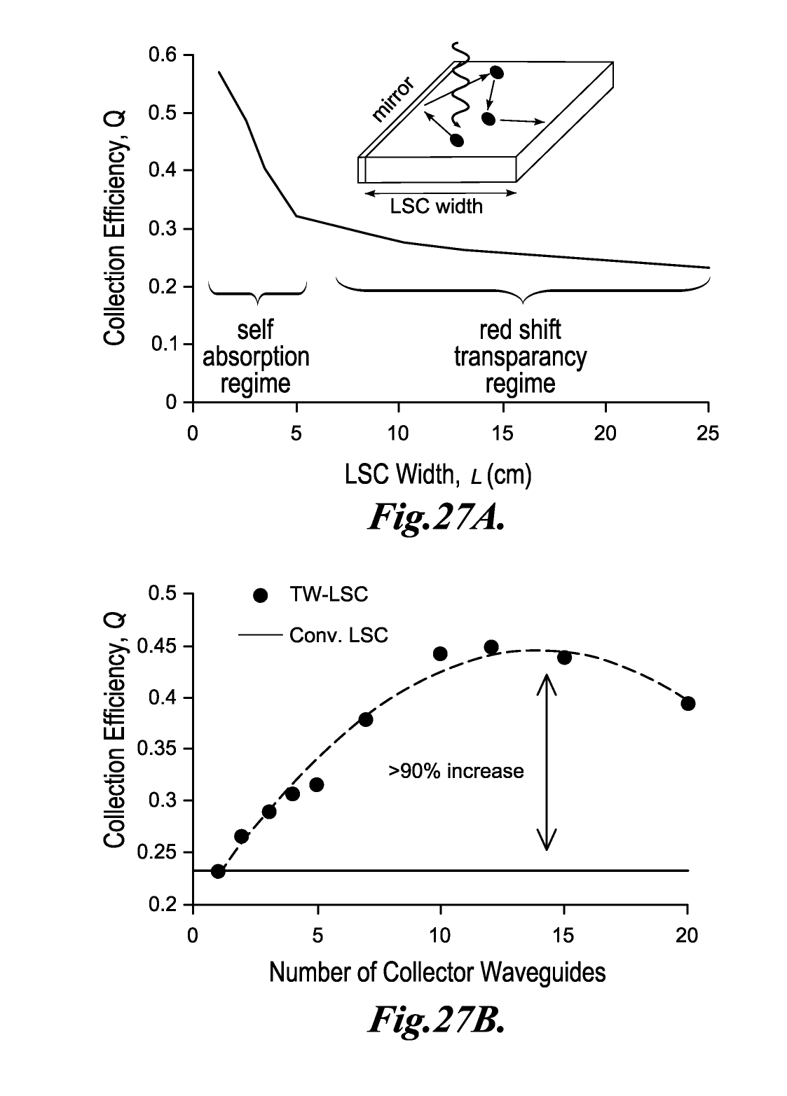

In fact, the peak performance of an optimized TW-LSC is significantly higher than this because we have not fully included the advantage TW-LSCs offer in increased efficiency by reducing self-absorption losses. To illustrate this point with a specific example, FIG. 27A shows the optical collection efficiency Q computed for a conventional LSC made from 0.2 cm thick poly(methylmethacrylate) (PMMA) dyed with 10⁻³ M Rhodamine 6 G. Q exhibits two decay regimes depending on collector dimensions: for a small LSC, Q is limited by self-absorption losses that rapidly attenuate efficiency over a distance L˜a few cm. For larger L, only red-shifted photons survive, which can propagate relatively free from self-absorption. Although these data are for a particular LSC, the material parameters and general behavior are representative of most devices studied to date, so these results may be considered typical. The key point is that most of the light is lost within the first few centimeters of the collector. Conventional LSCs require large concentrator areas to collect useful amounts of light and so must operate in the red-shift regime, where the efficiency is low. TW-LSCs use much smaller collectors, but more of them, enabling much higher efficiencies and consequently greater peak optical concentration.

FIG. 27B shows how even a simple TW-LSC nearly doubles collection efficiency for this particular case. The green line at Q=0.23 is for two L=25 cm wide, infinitely long conventional LSCs, sharing a common mirrored edge. The red data are calculated efficiencies for a L=50 cm wide, infinitely long TW-LSC with light collected from both edges. The TW-LSC has been divided into varying numbers of collector waveguides, each coupled to a TIR transport waveguide. Using the same conservative assumptions as above, we estimate the efficiency in this particular case can be nearly doubled. For the most efficient TW-LSC (12 collector waveguide pairs), losses in the transport waveguide due to scattering from junctions are 0.6 dB m⁻¹ and the geometric gain G=125.

These examples demonstrate that even simple TW-LSCs based on TIR transport waveguides incorporating the classic dyes used by early workers provide at least 10 times the energy concentration, and about twice the efficiency of conventional LSCs. As described in the following sections, performance can be increased even more through the use of transport waveguides based on GWPPMs, through incorporation of fluorophores selected to take specific advantage of the unique properties of TW-LSCs, and by employing more sophisticated device architectures whose design is guided by improved mathematical models.

Optical Models for Collector and TIR Transport Waveguides

An integrated numerical model has been developed accounting for absorption, emission, and scattering processes in the collector waveguide, as well as coupling and transport losses in the transport waveguide. This model has been used to optimize TW-LSC geometry and fluorophore parameters, as well as to constrain and characterize source coupling to GWPPMs, and has been addressed by standard photon transport simulated via Monte-Carlo methods.

Much work has already been done on modeling optical processes in planar LSCs, and a range of approaches to choose from are described in the literature, both theoretical and computational. Due to the relatively complex geometry of TW-LSCs and the need to understand specific phenomena and properties unique to this type of concentrator, we employ numerical models based on ballistic photon transport. The goals of the modeling are two-fold: (i) to describe the capture and conversion of sunlight via the luminescent dyes, and to use the calculation to determine the angle-resolved intensity and wavelength distributions leaving the collector edge, and (ii) to then model the capture and transport of the collected light to the PV cells via a TIR transport waveguide. Because we use a numerical approach, it is relatively straightforward to include the full details of a chosen fluorophore's absorption and emission spectra, and therefore the energies, as well as the trajectories of photons can be accurately predicted. This enables direct comparison with the spectroscopic measurements. In addition, the models allow us to probe various geometries in order to assess and optimize TW-LSC performance by computationally exploring alternative geometries before they are fabricated.

The basic approach is to simulate the trajectories of individual photons, which arrive with an energy distribution given by the AM1.5 solar spectrum either as diffuse or specular light, and then move according to probabilistic rules, interacting with fluorophores and the waveguide boundaries. As the photon travels, a free path length is chosen based on its wavelength-dependent probability of absorption or scattering, interaction with boundary surfaces and waveguide matrix material are taken into account, reflecting when the angle with the boundary lies outside the critical cone, and escaping (and being lost) when the angle is within the critical cone. The process is then repeated for a large number of photons.

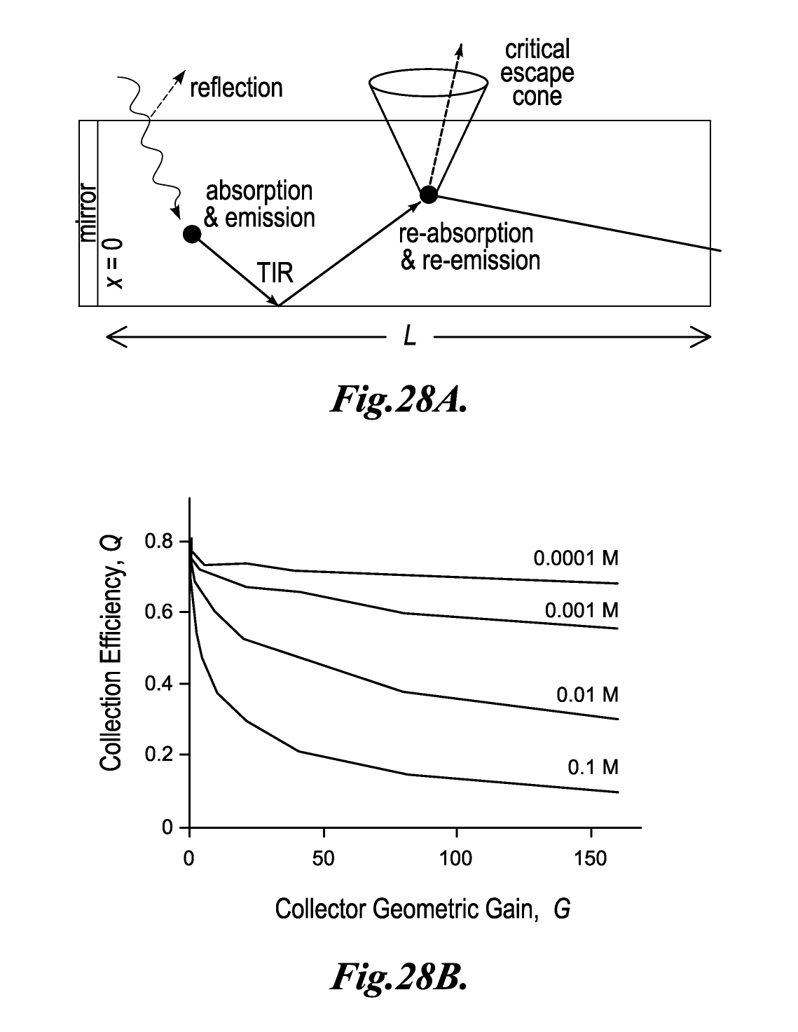

In conjunction with the preliminary experiments mentioned previously, we have performed calculations based on simulations of a simplified version of this model incorporating just the subset of processes illustrated in FIG. 28A. As an example, FIG. 28B shows the collection efficiency Q for a collector of geometric gain, G based on parameters appropriate for the dye DCM in a 0.2 cm-thick PMMA collector waveguide. The self-absorption and red-shift regimes discussed earlier are apparent, particularly for higher concentrations. These calculations employ a new approach for self-consistently calculating the absorption cross-section, and hence the photon mean free path; in brief, the absorption coefficient is accurately given by the cumulative function based upon the absorption distribution, i.e., C(∈)=∫₀^{∈}A(ε)dε, with A(ε) the experimental absorption distribution and C(∈) the probability that a given energy lies below the absorption curve. The results are consistent with those for DCM (FIG. 28B).

Additional model variations incorporate the entire collector/waveguide geometry, as well as additional effects including scattering and absorption by the polymer matrix, the Fresnel relations and effects of surface roughness at the boundaries, polarization-emission/absorption asymmetries, and temperature-dependent anti-stokes processes for the dye molecules.

GWPPM Transport Waveguide Development

GWPPMS as used in the embodiments herein have several important characteristics. First, under certain conditions, coupling of light into GWPPMs is predicted to occur with low insertion loss and is unidirectional. In other words, the approach minimizes scattering losses from collector-transport waveguide junctions mentioned above that ultimately limit the performance of TIR transport waveguides. Second, the multi-layer geometry allows for tailoring excitation frequencies, dispersion properties, and the related resonance bandwidth, necessary to match fluorophore emission and minimize insertion losses. Third, the waveguide is mostly transparent to non-resonant light, allowing unharvested solar photons to be collected in a second TW-LSC using a different fluorophore below the first one, or used for photothermal applications such as heating water.

GWPPMs are surface-constructed waves, but they have a large electric field amplitude localized to the central dielectric layer, more typical of standard guided wave modes. GWPPMs are therefore fundamentally distinct from ordinary surface plasmon polaritons (PPs) at a dielectric/metal boundary, which suffer rapid energy loss due to Ohmic damping that limits propagation lengths to a few mm. For the GWPPMs, the electric field profile is more similar to a conventional dielectric waveguide, so much smaller transport losses are anticipated.

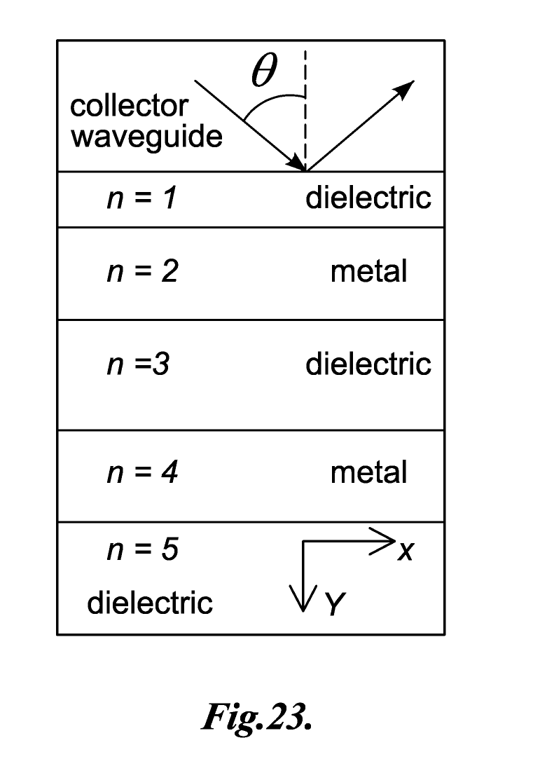

A new approach based on a metal-dielectric-metal structure supporting a surface-constructed guided-wave plasmon polariton mode (GWPPM) is described. In particular, we have found a region of the GWPPM parameter space that lends itself to the conversion of light in the frequency range corresponding to the peak emission spectra of the fluorophores described in the previous section. In addition, the collector geometry also lends itself to an application of attenuated total reflection (ATR), a technique for exciting and detecting surface-waves. The structure of the GWPPM transport waveguide is shown in FIG. 21A, and in more detail in FIG. 23.

To analyze the waveguide, first the two-metal-film separated by a dielectric spacer is analyzed, and a dispersion relation—i.e., the relationship between the frequencies and allowed wavevectors for the elementary excitations—is calculated, so that candidate modes with the right combination of frequency and propagation vector may be identified. Second, the system is set up in the ATR configuration, with a thin film (or air gap) separating the top metal surface from the collector waveguide material, so that ordinary electromagnetic waves may couple the surface-constructed two-metal-film excitations. The calculated ATR reflectance then provides a quantifiable check on the coupling efficiency between the electromagnetic waves in the prism dielectric and the SPP modes of the bi-layer waveguide.

The first step in finding the collective-mode dispersion relation is to solve the electromagnetic wave equation appropriate to each region, and match the solutions across regions using the appropriate boundary conditions. We first write the general wave equation (we assume the system is not magnetic, and thus μ=1 everywhere):

$$∇ \times ∇ \times \vec{E} = - \frac{1}{{c}^{2}} \frac{{\partial }^{2} \vec{D}}{\partial {x}^{2}} ,$$

where \vec{E} and \vec{D} are the electric and displacement field vectors, respectively. We then assume plane-wave-like solutions in each region, e^{i(\vec{k}-\vec{r}-ωt)} (where \vec{k} and ω are the polariton propagation vector and frequency, respectively), and given linear, isotropic media, the constitutive relation \vec{D}= [symbol] \vec{E} immediately gives a simple two-component wave equation in terms of the electric field vector alone (2-component because we note that \vec{k} \hat{z}=0 for p-polarized modes). The two-component system admits linearly-independent solutions if the following relationship holds:

k_{ny}²=ω₀²∈ₙ−kₓ² Eq. 1

where

$${ω}_{0} = \frac{ω}{c} ,$$

and n denotes the appropriate layer from FIG. 23. We now use the two-component relation to write down a general solution for the electric field vector in a given region as a superposition of waves traveling in the +y and −y directions; denoting the tangential amplitudes of the plus- and minus-traveling waves as Aₙ and Bₙ, respectively, we find:

$${E}_{n} = [ \begin{matrix}\hat{x} \\ \frac{{k}_{x}}{{k}_{ny}} y\end{matrix} ] {A}_{n} {e}^{i ( {k}_{x} x + {k}_{ny} y - ω t )} + [ \begin{matrix}\hat{x} \\ - \frac{{k}_{x}}{{k}_{ny}} y\end{matrix} ] {B}_{n} {e}^{i ( {k}_{x} x - {k}_{ny} y - ω t )} \qquad Eq . 2$$

The next step is to match the solutions to Eq. 2 at each interface, utilizing the appropriate boundary conditions. For the present geometry, the tangential components of \vec{E} and the normal components of \vec{D} are continuous at each interface. Writing out the boundary conditions produces an 8x8 matrix equation for the electric field components B₁ through A₅, and the coefficient matrix is a function of the parameters ω and kₓ. We choose the component of the wavevector parallel to the interfaces as a parameter because this component is conserved across all boundaries, and the perpendicular component k_{ny} is a function of kₓ from Eq. 1. The polariton dispersion, ω(kₓ), that provides a map of the allowed SPP excitations, is calculated by requiring that the determinant of the boundary condition matrix vanish, thereby ensuring linear independence of the solutions to Eq. 2 in every region. Some numerical examples, and the model proposed for the solar light transport waveguide, are given next.

We consider only the geometry of FIG. 23 in this example; in this case, the dielectric constants of the layers are given by ∈_{1,3,5} in the insulating layers, and by the model function

$$∈ ( ω ) = 1 - \frac{{ω}_{p}^{2}}{{ω}^{2}}$$

in the metal layers (n=2,4). Here ωₚ is the plasma frequency, and we have neglected damping for brevity. In what follows, we will scale the variables in a convenient fashion for studying the general properties of the system; all frequencies will be in units of the plasma frequency,

$$Ω = \frac{ω}{{ω}_{p}} ,$$

while the thicknesses of the films are scaled by the characteristic length

$$\frac{c}{{ω}_{p}} ,$$

and the wavevectors are multiplied by this length, i.e., we employ the unitless parallel wavevector K=kₓc/ωₚ. The implications for real systems are explained below.

Some general features of PP's are as follows: In all cases presented here, the PP modes break roughly into two types, characterized by the normal component of the wavevector k_{ny}. For pure real k_{y}, the solutions are wavelike inside a given layer (examine the effects of real and imaginary k_{ny} in Eq. 2), while for pure imaginary k_{y}, the modes in a given layer are surface waves which decay exponentially into the material. The condition for surface polaritons in a given region is given by Eq. 1, i.e., K<∈(ω/c)², or, for conducting layers

$$ω < {( {c}^{2} {k}_{x}^{2} + {ω}_{p}^{2} )}^{\frac{1}{2}} ,$$

and for dielectric layers,

$$ω < \frac{{ck}_{x}}{{∈}_{1 , 3 , 5}} .$$

These relations mark the boundaries of the ‘bulk modes’ and the ‘light line,’ respectively, within a given material. The placement of the light line is crucial to what follows.

A typical ‘pure’ surface-wave constructed PP exists only for frequencies less than the parallel wavevector; however, in the present case, we wish to create a composite system—the guided-wave surface plasmon polariton. Here, we note that the if the dielectric constant (i.e., the index of refraction) of the spacer dielectric (layer n=3) is larger than that of the substrate, it will be possible to have wave-like solutions inside the spacer dielectric, coupled to surface-modes on the metals and the exterior materials. The upshot is an elementary excitation that propagates parallel to the interfaces, and which is largely localized in the spacer dielectric, away from the damping effects of the metal films. Now, since the PP modes do not lie on the light line in any given material, they are not accessible to ordinary reflection experiments: propagating electromagnetic waves are, of course, constrained to the light line in any material. The PP modes may be accessed via other surface-wave phenomena, such as the evanescent waves created by total internal reflection at an interface. This is the basis for the ATR excitation method.

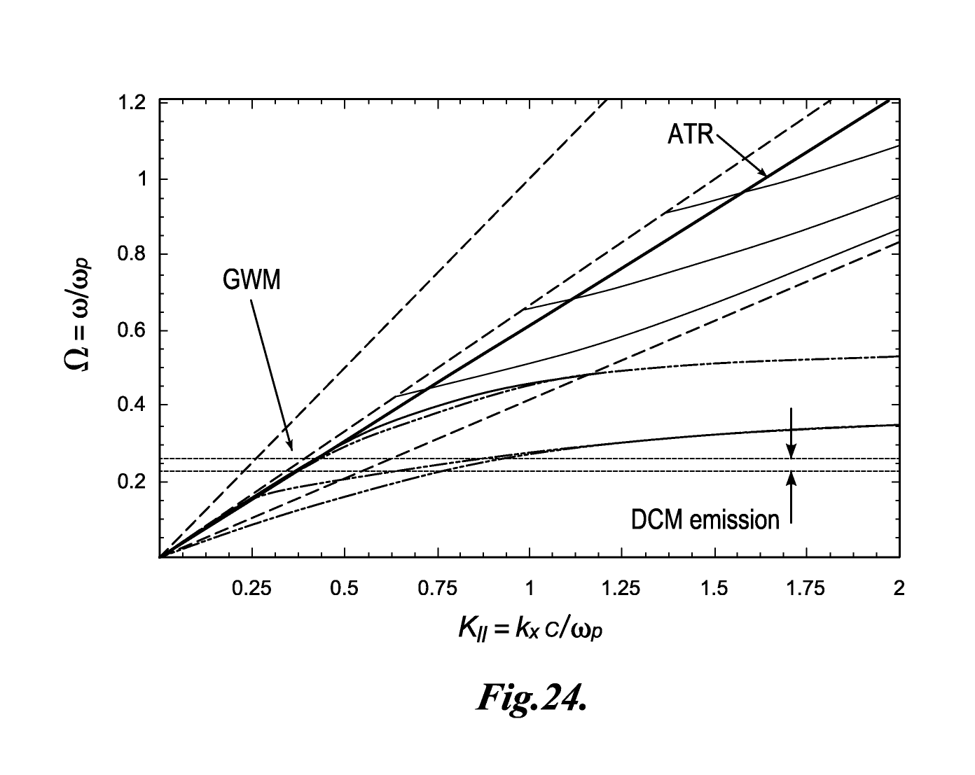

The initial system is composed of two gold films, separated by a spacer of strontium titanate (a high-refractive-index material, transparent in the visible), resting on a thick substrate of SiO₂, and capped with a thin layer of SiO₂. An example of the dispersion Ω(K) for this type of system is depicted in FIG. 23. The system has thicknesses given by t_{2,4}=1.11c/ωₚ (roughly 25 nm for gold, with a plasma frequency of 9 eV), and t₂=5t_{2,4} (125 nm of SrTiO₃), and the dielectric constants are given by ∈₁=∈₅=2.25, appropriate to SiO₂, and ∈₂=5.8, appropriate to SrTiO₃. Note the presence of three light lines (straight dashed lines); these correspond to the free-space light line, the SiO₂ line, and SrTiO₃ line, largest slope to smallest, respectively. Therefore, the region of interest here is between the SiO₂ line and the SrTiO₃ line, since in this region the system supports exponentially decaying waves in the SiO₂, and wavelike-modes in the SrTiO₃. In particular, we are interested in the frequency range corresponding to the peak of the emission of the dye phosphor in the collector, since this frequency will be the predominant light impinging on the waveguide. For the fluorescent dye DCM used in the preliminary investigations mentioned above, the frequency of interest is 2.187 eV, or in units of the plasma frequency of gold ω_{DCM}/ωₚ=0.243. This region is shown by the arrows in FIG. 24, where the parallel lines indicate the FWHM of the DCM emission distribution (note the PP modes existing in the region between the two dielectric light lines in the correct frequency regime).

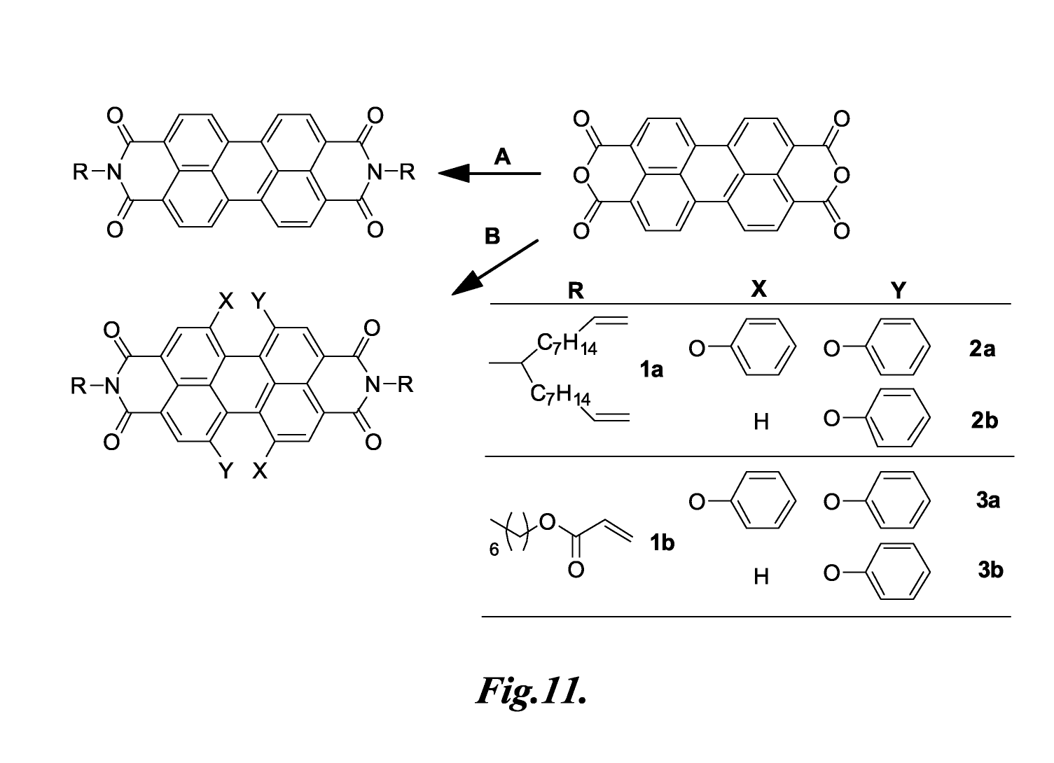

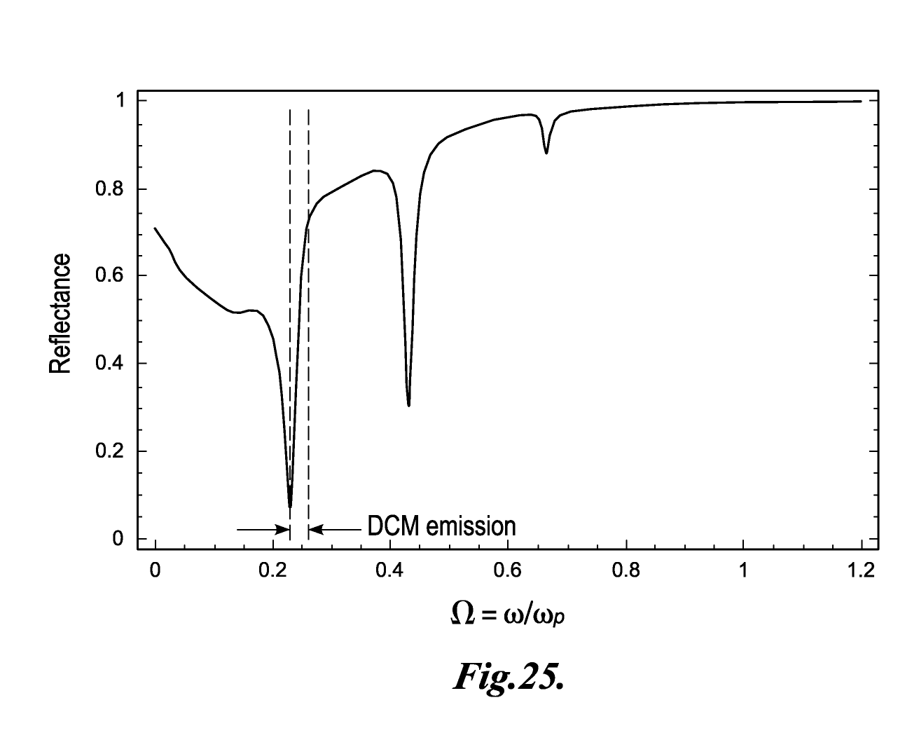

As mentioned above, ATR is a preferred method to excite the PP modes. The GWPPM transport waveguide interface acts as an appropriate coupler, since the angle of the collector fin axis to the top surface of the waveguide is greater than the critical angle between the collector matrix material and the SiO₂ top spacer. In FIG. 25, we show the calculated ATR response, plotted as reflectance vs. frequency Ω, for the system above. The “ATR” line in FIG. 11 corresponds to the line scanned by the ATR reflectance experiment—this line is parameterized by the angle of incidence and the collector dielectric constant: ω=ckₓ/sin θ\sqrt{∈_{c}}. Note that where the ATR line crosses the modes in FIG. 24, dips appear in the ATR reflectance of FIG. 25. The mode of particular interest corresponds to the deepest reflectance dip (which is the most efficient coupling to the SPP mode) that occurs at a frequency very near the peak in the dye emission as indicated on the figure.

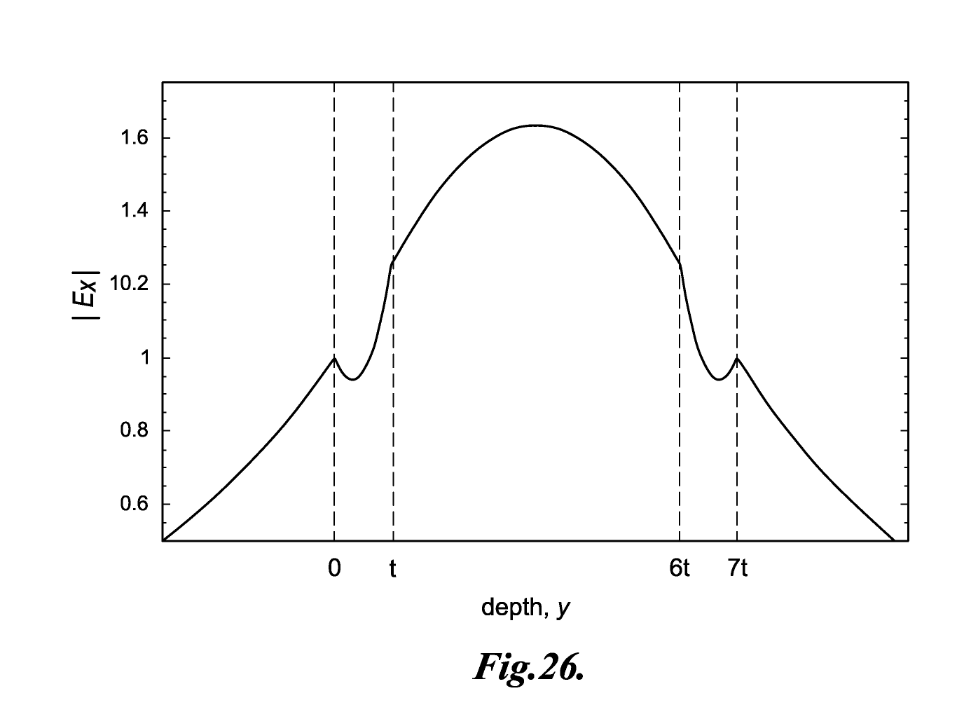

As a final check on the efficacy of the SPP mechanism, we examine the profile of the electric field amplitudes in the various media for the SPP mode of interest. In particular, the lowest mode of the SPP braches at the appropriate frequency is depicted in FIG. 26. Here the absolute magnitude of the tangential component of the electric filed is plotted as a function of depth into the structure; note the dramatic localization of the electric field to the SrTiO₃ layer, which lies between 1 and 6 on the horizontal axis. The vertical dashed lines are the film boundaries.

The calculations presented above represent a theoretical validation of a GWPP light transport system. Significantly, the calculations show that reasonable variations in refractive index and film thicknesses can be tolerated, and functional waveguides can be constructed using practical fabrication methods.

### EXAMPLES

### Example 1

### Oriented LSC Preparation and Testing

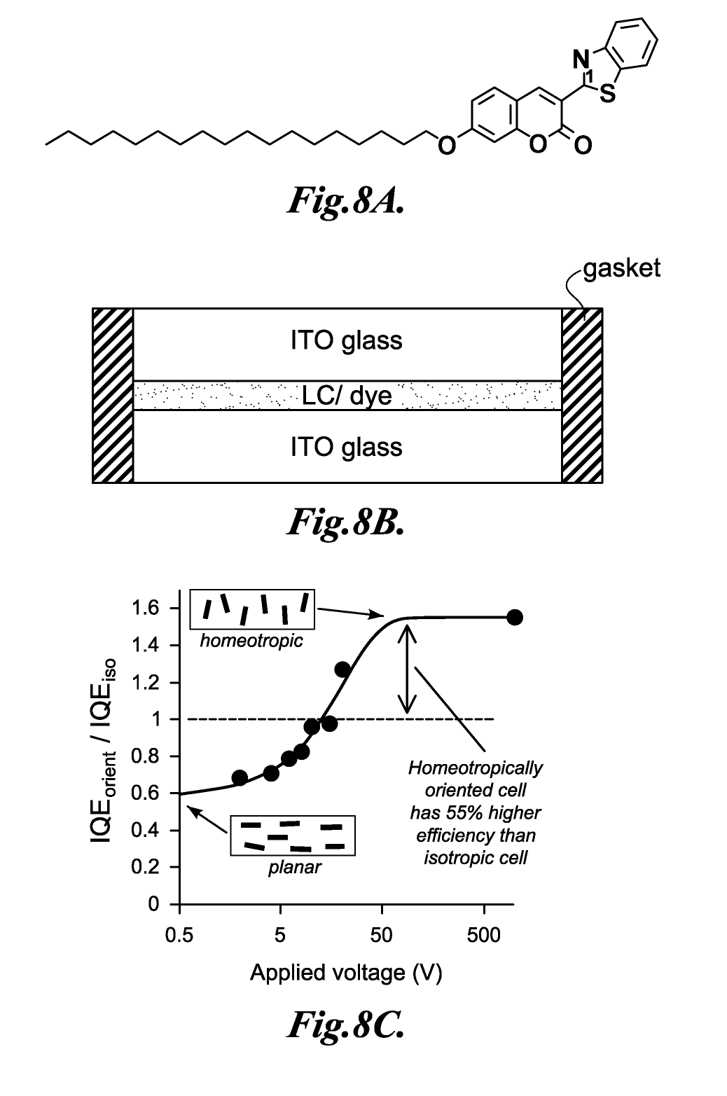

Prototypes LSCs were prepared using the commercially available fluorescent dye 3-(2-Benzothiazolyl)-7-octadecyloxy-coumarin dissolved in the nematic LC host 4′-pentyl-4-cyanobiphenyl. An indium-tin-oxide (ITO) glass cell coated with rubbed polyimide to induce planar anchoring was filled with the dye/LC solution (FIG. 8B). Order parameters determined by steady-state polarized fluorescence and UV-Vis absorbance spectroscopy were P₂( μ̅ₑ)=0.25, P₄( μ̅ₑ)=0.25, P₂( μ̅ₐ)=0.6. β was measured at low temperature in propylene glycol and found to equal 31°,¹⁹ and S_{abs}=0.7. The properties of this material were therefore most similar to those of line 3 in FIG. 7.

FIG. 8B illustrates a prototype LSC device constructed by filling an ITO/glass cell with the coumarin dye shown in FIG. 8A dissolved in the LC host 5CB. Edge emission is detected under UV illumination. The plot in FIG. 8C shows the internal quantum efficiency (IQE) of the cell in the nematic phase (circles and line fit) relative to the isotropic phase (dashed line). Above the Freedericks transition (˜7V) alignment is homeotropic and efficiency increases by 55% relative to the same isotropic cell, in qualitative agreement with predictions from the model in FIG. 7.

The filled cell could be switched between planar and homeotropic orientation by applying a voltage, thus allowing measurement of two configurations in a single cell. Measurements were performed at room temperature (nematic phase) and 55° C. (isotropic phase) in order to compare oriented vs. isotropic cells. For these preliminary measurements we lacked the equipment necessary to measure the OQE directly, but we could determine the closely related internal quantum efficiency IQE=OQE/(fraction of incident photons absorbed).

Results from one prototype LSC are shown in FIG. 8C. At high applied voltage, when n̅ and μ̅ₑ were homeotropic, the material was 55% more efficient at concentrating light than the same cell in an isotropic state. This remarkable increase was based solely on alignment. It agrees with the results of preliminary simulations, as can be seen by comparing the (4) and (3) lines in FIG. 7 which are for isotropic and oriented materials with parameters similar to the experimental coumarin-based material.

To summarize, preliminary Monte Carlo and experimental results predict that by controlling fluorophore alignment it is possible to prepare materials that perform as well or better than the best LSC fluorophore yet discovered, even using conventional, strongly self-absorbing dyes. Further improvements by another factor of 50%-100% are possible through better controlled alignment and by developing dyes tailored to exploit the unique optical characteristics of the proposed oriented waveguide materials.

The invention is informed by the wealth of information available on the behavior of dyes in LC hosts extending back 40 years to the invention of the dye-doped LC display. Orientational properties, solubility, absorption and emission spectra and photostability measurements on over 3,000 dyes have been examined in dozens of thermotropic LC solvents. Likewise a wide variety of polymers and liquid crystal polymers have previously been prepared and used to orient luminescent groups and guest molecules, although as far as we are aware they have never been investigated as light harvesting waveguides or in the context of LSCs.

Controlling Fluorophore Orientation. Optically transparent oriented films can be prepared covering large areas, capable of aligning the fluorophores discussed below while serving as sufficiently good solvents to prevent aggregation at the required dye concentrations (˜10⁻⁴ M). To achieve these so-called “reactive mesogens” (RMs), a class of photopolymerizable low molecular weight LCs are employed. Unlike liquid crystal polymers, RMs exhibit a liquid crystalline phase as monomers. They have a relatively low viscosity compared to liquid crystal polymers, and upon cooling from the clearing point it is possible to form large uniformly oriented monodomains that can be polymerized in the LC state by exposure to UV light. This produces a densely crosslinked solid in which LC-like order is permanently fixed. Their anisotropic properties and ease of processing make them especially useful for the present application.

One additional advantage is that uniform RM films can be applied and oriented over large areas by spin casting unpolymerized monomer onto a glass or plastic substrate coated with an appropriate alignment layer to induce the desired orientation (planar, homeotropic, or tilted). Fluorophores can be aligned through either the guest-host effect, or through covalent incorporation. Photopolymerization locks in the oriented state producing a photo- and thermal-stable film Order parameters for dyes incorporated in LCPs have been reported to be in the range P₂=0.7-0.9, comparable or higher than monomeric thermotropic liquid crystals.

Additionally, prior to polymerization RMs behave like conventional thermotropic nematic LCs. This means they can be used to fill dye-doped LC cells, which are an extremely convenient platform with which to rapidly prototype new fluorophore and orientational concepts. Among the advantages of unpolymerized RMs are: (i) Filled cells can be switched between planar and homeotropic orientations by application of a field, or easily brought into the isotropic state by heating. This allows the spectral and optical characteristics of up to three different orientational states to be tested in a single prototype LSC, as was done for the preliminary materials reported above. (ii) Intermediate orientations of n̅ can be achieved using different surface treatments to control the pretilt angle. (iii) Fluorophore concentration and composition is readily controlled and adjusted.

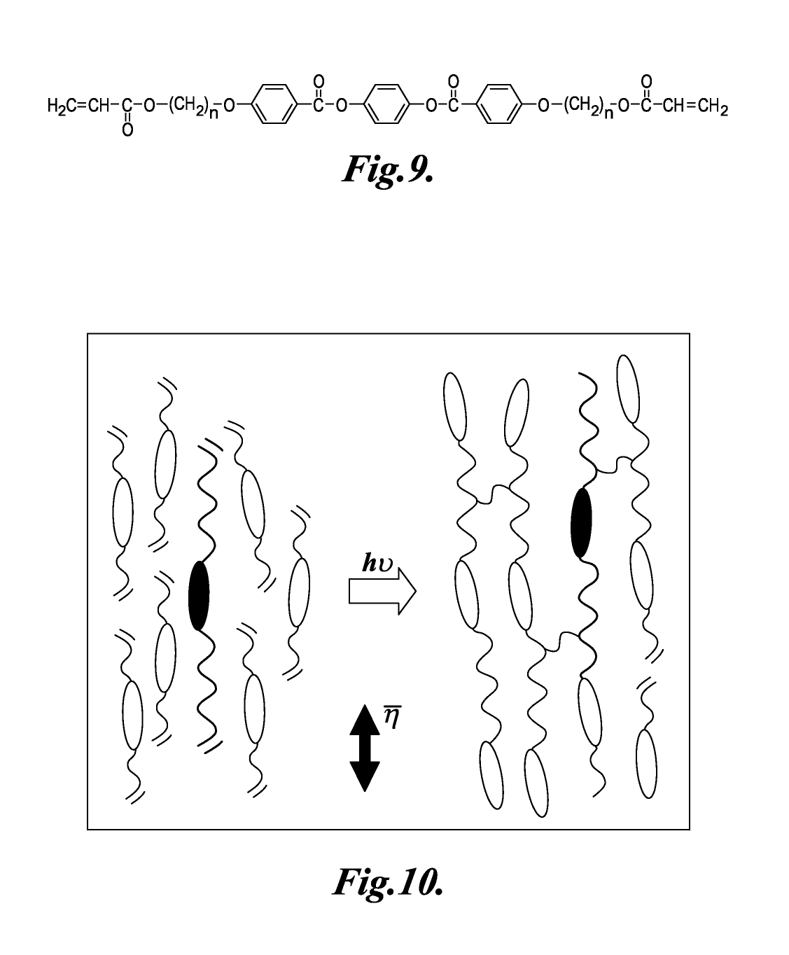

We use, in an exemplary embodiment, the diacrylate family of RMs, shown in FIG. 9. These materials form a photopolymerizable nematic phase whose transition temperatures can be tuned through the linker length, n, and by mixing monomers with differing linker lengths. For example the eutectic formed by combining the two compounds in FIG. 9 in a 4:1 mixture of RM257 (n=3) and RM82 (n=6) forms films of particularly high optical clarity because crystallization is suppressed.

Fluorophores are incorporated and aligned as illustrated schematically in FIG. 10. Di- and/or monoacrylate functionalized perylene bisimide fluorophores are oriented prior to photopolymerization in the RM LC via the guest-host effect. The synthetic preparation of perylene dyes is described below. Polymerization is carried out via photo-initiated free-radical polymerization of oriented spin-coated films or RM-filled cells containing a small amount of a photoinitiator such as Irgacure 651 (Ciba, λₘₐₓ=335 nm).

Fluorophore Synthesis. Fluorophore monomer cores are used that have a number of important fundamental properties. These characteristics are: 1) high photoluminescent quantum yield (η_{φ}), 2) either a wide spectral coverage with good photovoltaic responsivity matching or the ability to be functionalized to provide a tandem set that has wide spectral coverage with good photovoltaic responsivity matching, and 3) high photostability. In addition to these fundamental properties, we also use molecules that have specific tailorable properties such as a) orientability in a liquid crystal, and b) high solubility/absorptivity.

One core that possesses all of these properties is the perylene tetracarboxylic acid bisimide (perylene bisimide) dye family. Perylene bisimides (PBIs) have η_{φ} near unity, high photostability, and their absorption/emission can be tuned to cover essentially the entire visible spectrum (from green to red). These PBI cores can also be functionalized to prepare soluble, orientable analogs.

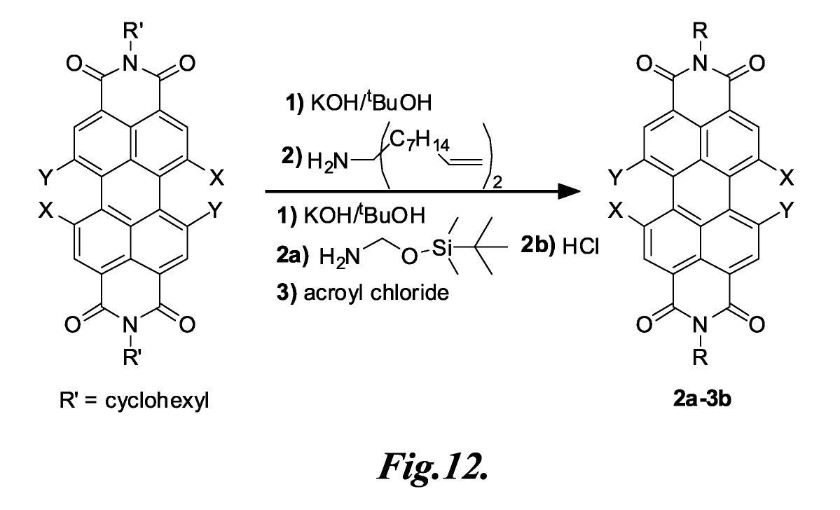

In general, we adopt two common approaches to functionalize PBIs to produce fluorescent monomers capable of being polymerized with RMs to produce oriented polymer films (FIG. 11). The first is by reaction of the peripheral bisanhydrides with the appropriate enylamine to introduce suitable crosslinkable imide linkages (route A). The second is the derivatization of the aromatic core via bay substitution (route B and FIG. 12). The photophysical characteristics of identical aliphatic substituted PBI dyes are listed in Table 2. The absorption/emission characteristics of the synthesized monomers are not affected by the addition of the olefinic/acrylate groups due to the well known nodes present at the imide nitrogen in both the HOMO and LUMO π-π orbitals of the PBI cores. All four dyes have η_{φ} near unity and extremely high molar absorptivities. These dyes are optimal for orientation in LSCs utilizing RM-based polymers because they themselves have been shown to exhibit thermotropic liquid crystalline properties. Functionalized perylene dyes are also ideal candidates based on the fact that order parameters ranging from P₂=0.69-0.81 have been measured for the PBIs in liquid crystal mixtures.

Covalent incorporation of the fluorophores into polymerized RM networks is achieved by photo-initiated polymerization of the unsaturated monomers shown in FIGS. 11 and 12. This aligns μ̅ₑ nearly parallel to n̅, since the transition moment for emission lies along the long molecular axis in PBIs. Some fine tuning of the angle between them (θₑ, FIG. 3) is possible through a combination of asymmetric substitution of R in FIG. 12, and by adjusting the steric bulk of groups at the bay positions X and Y. PBI monomers that are substituted with an acrylate have been reported in the literature and crosslinking of the swallow-tail dienylamine la has also been explored.

TABLE 1
Optical Properties of Selected Perylene Dyes in Chloroform

| Aliphatic | | | | |
|---|---|---|---|---|
| Analog | λ_{abs}/nm | ε/M⁻¹cm⁻¹ | λₑₘ/nm | η_{φ} |
| 1a | 526 | 88000 | 533 | 1.00 |
| 1b | 526 | 23000 | 531 | 1.00 |
| 2a | 573 | 45300 | 608 | >0.96 |
| 2b | 549 | 55000 | 578 | 1 |

Measuring LSC optical properties. As discussed above, two types of samples are presented: (1) ITO-glass cells filled with unpolymerized RM/fluorophore solutions, and (2) spin cast or mechanically spread photopolymerized films The former are useful for rapid testing of fluorophore and alignment concepts and enable three orientational states to be determined for each sample prepared (planar, homeotropic, and isotropic) by application of a field to switch the cell or by heating above the clearing point. The latter can be applied over much larger areas, and is better suited for future practical applications.

Optical properties can be measured using the setup shown in FIG. 20. A custom fluorometer exciting the sample through a fiber optic allows the edge output to be measured as a function of distance (x in FIG. 20) in order to determine transport loss rates. Emitted light is collected at various angles (θ), and it is possible to locate the emission collection fiber at various positions around the LSC to measure the angular distribution of edge and facial emission. This arrangement allows for the determination of absolute OQE vs. sample dimensions and excitation wavelength, which are the two fundamental performance metrics for any LSC.

Experimental Determination of P₂( μ̅ₐ), P₂( μ̅ₑ), P₄( μ̅ₑ), and β

For each sample we determine orientational order parameters in the sample frame of reference for the absorption and emission transition moments associated with S₁←S₀ and S₁→S₀, as well as the angle β between them. β is determined from the fundamental anisotropy

$${r}_{o} = \frac{1}{5 〈 3 {cos}^{2} β - 1 〉} ,$$

measured using steady-state polarized fluorescence spectroscopy at low temperature in an amorphous polymerized sample. Several methods are available for the determination of the order parameters P₂( μ̅ₐ), P₂( μ̅ₑ), and P₄( μ̅ₑ), depending on the orientation of n̅ with respect to the plane of the film. For determination of P₂( μ̅ₐ) in the homeotropic configuration we use UV-Vis absorption spectroscopy.

As mentioned above, most prior research aimed at improving LSC efficiency focused on the use of low self-absorption fluorophores, usually accomplished by choosing dyes or dye systems with the largest possible Stoke's shift (large S_{abs}). Oriented fluorescent waveguides present an opportunity to shift the focus to a different set of design criteria, enabling exploration new concepts exploiting the unique optical characteristics of aligned dyes. Two new concepts based on this principle are described

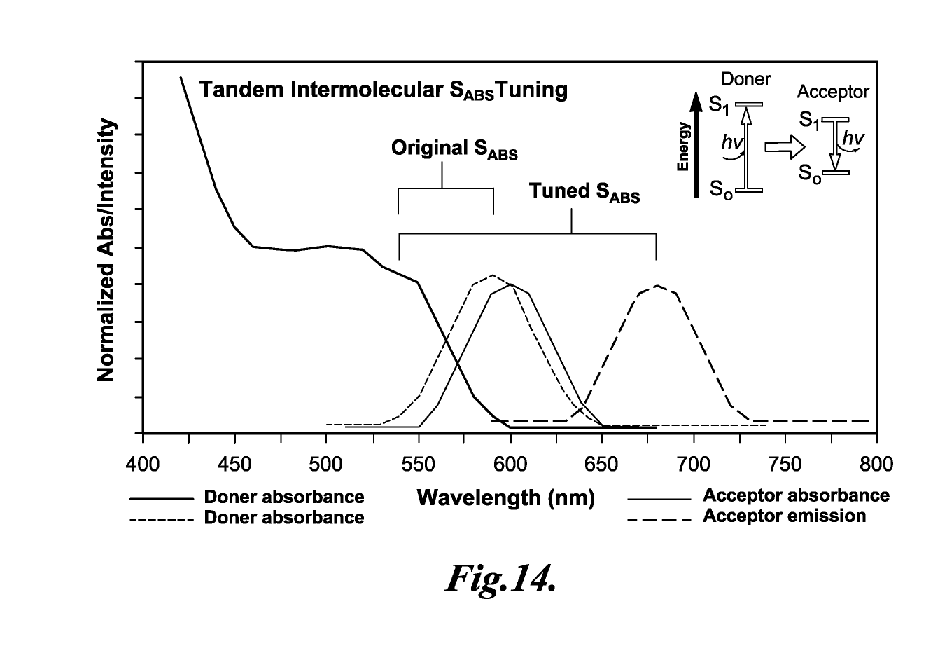

Mixed orientation fluorophore cascades. As described, one disadvantage to oriented materials based on fluorophores with small β is that μ̅ₐ is aligned unfavorably to absorb incident sunlight. Consequently a higher dye concentration is required to compensate, leading to greater self-absorption-related losses. One way to address this problem is through tandem fluorophore mixtures containing both isotropic and oriented components. FIG. 14 illustrates a hypothetical donor/acceptor system where the S_{ABS} is tuned through the use of intermolecular energy transfer between an isotropic emitter (donor) and an aligned acceptor. As illustrated in FIG. 14, the isotropic component (donor) is designed to absorb a wide range of the solar spectrum and transfer its energy to an oriented red emitter (acceptor). The advantages to this method are twofold: 1) to reduce the required concentration of the aligned red emitter (acceptor) and 2) it allows us to relax the requirement of low self-absorption for the LSC fluorophores. The concept is similar to the strategy of utilizing Förster energy transfer to reduce self-absorption, but since we are interested in materials with a low concentration of non-aggregated fluorophores (˜10⁻⁴ M, or mean dye-dye separation ˜25 nm), the energy transfer process should be dominated by radiative transfer. S_{abs} can effectively be tuned through the use of fluorophores whose emission spectra match the absorption of the oriented acceptor. The tuned S_{abs} then becomes the difference in the absorption of the donor and the emission of the acceptor.

Two representative types of donors using this scheme are provided, both selected to match red emission of the PBI fluorophores discussed in the preceding section. The first is CdSe/ZnS quantum dots (QDs), which are desirable from the standpoint of having very broad spectral coverage and tunable emission, but are otherwise not very suitable for conventional isotropic LSCs because of their relatively low photoluminescent quantum yields and large self-absorption. When used as donors in the mixed isotropic/oriented fluorophore cascade system however, the latter properties matter much less than the corresponding properties of the acceptor dye.

The second donor system is based on the use of cascading isotropically oriented dye mixtures from the BASF Lumogen F dye series. These dyes have extremely high quantum yields, excellent photochemical stability, and appropriate mixtures can be used to cover nearly the entire solar spectrum, making them very well suited for this purpose. For example, a mixture of Violet 570, Yellow 083, and Orange 240 can be used as isotropic donors. The emission of the latter at 538 nm overlaps well one of the aligned red emitters (573 and 549 nm, respectively).

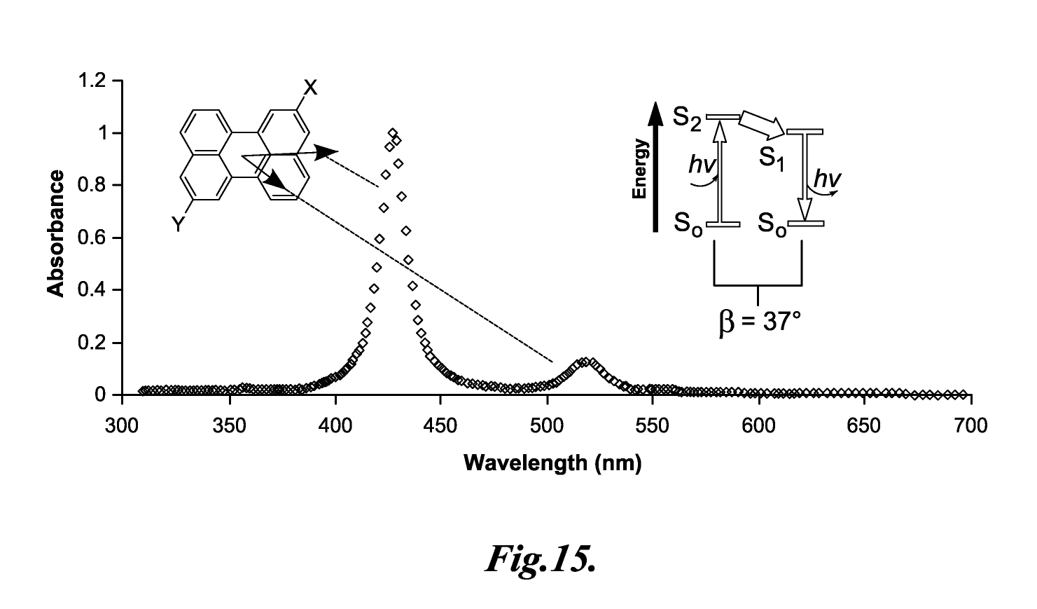

Designing fluorophores for large effective β. The second fluorophore design concept targets β directly, by determining—first computationally and then experimentally—appropriately substituted derivatives of the PBI core with the largest possible β. Selective addition of electron donating and withdrawing groups is used at the bay positions in order to add a new weakly allowed electronic transition, resulting in a molecular energy level diagram qualitatively resembling a three-level laser (FIG. 15). Self-absorption losses are then mitigated in two ways: i) the emission and absorption are generated via different internal transitions, and ii) the angle β may be controlled because it now depends upon the transition dipoles associated with a transition to and from different molecular orbitals with different charge density distributions.

Thus, within a single molecule with a large onset absorption (i.e., onset or low-lying transitions, so that π-correlated electrons are the principal components) in the visible range, a suitable substitution to the periphery of the dye core that couples weakly to the π-orbital structure can introduce a weakly-optically-allowed orbital slightly below the onset transition. The absorption/emission process may now utilize two electronic transitions, a higher energy mode with a large oscillator strength for absorption (what is now S₂←S₀) coupled internally to the lower-energy excited state (i.e., S₁), so that fluorescent emission occurs via the low-energy transition (S₁→S₀). If the oscillator strength of the low-energy transition is small relative to the high-energy transition, and if the internal conversion is efficient, then the emission process from the low-energy transition will dominate absorption. This provides an effective β measured as the difference between the dipoles associated with the different transitions, which will be determined by differences in the electronic structure for the two excited molecular orbitals, which is in turn determined by the properties of the substituted structures.

Extensive work has been carried out utilizing a recently-introduced model for including correlations into the optically-allowed molecular orbitals of large molecules. The model consists of a particle-hole transformation performed on the fully-correlated n-electron interacting system constructed of the pi-electrons on an assumed rigid sigma-bond skeleton. The key is a rigorous mapping between the low-energy optically-allowed molecular states, which are highly spin correlated due to the dipole induced charge transfer, and the particle-hole picture with repulsive on-site interactions.

FIG. 15 illustrates the model-predicted absorption (dotted curve) for the doubly-substituted perylene system illustrated in the left-hand inset (which includes the predicted transition dipoles for each peak). The two transitions participate in the absorption/emission process as illustrated schematically in the right-hand inset.

Note the small onset peak at 525 nm below the primary perylene absorption at 425 nm. The inset shows the schematic of the absorption-internal transfer-emission process described above. β for the levels shown is predicted to be 37°, two to three times larger than the native perylene core.

### Example 2

### Fabrication and Experimental Characterization of GWPPM Transport Waveguides

GWPPM transport waveguides are constructed in the multilayered structure shown in FIG. 23, with layers n=2 and 4 made from Au, layers n=1 and 5 made from SiO₂, and the spacer layer n=3 made from SrTiO₃. These exemplary devices employ e-beam and sputter coating deposition, but it may be possible to form the oxide layers using sol-gel techniques to reduce fabrication costs and cover large areas.

An initial systematic characterization of the waveguides is carried out in two broad steps (as has been successful for studying polaritons in similar systems): (i) the identification of guided modes is first made via a fixed-wavelength, angle-resolved measurement to find a point on the PP dispersion for reference, and (ii) a fixed-angle frequency-resolved measurement is carried out, to identify the various modes of the system and produce an experimental plot like the one shown in FIG. 25; sweeps in frequency at constant angle can be used to map the whole of the SPP dispersion for a given sample, and can be directly compared to theory. The basic experimental system consists of a laser source (fixed frequency part), and a leaded-flint-glass prism placed on top of the SiO₂ cap layer. The incident angle inside the prism is controlled (for a range of angles greater than the critical angle), and the reflected light is collected. A white-light source is utilized for the frequency-scanned experiment, with other components unchanged. The results of the initial characterization help to pin down values for damping parameters within the gold, as well as other loss mechanisms, which can be fed back in to the calculations of the full system, and used to guide future sample development. Lastly, measurement of the global waveguide efficiency is characterized via comparison of the ATR reflected intensity, the light collected from the waveguide edge, and to theory, thereby determining coupling and transport losses.

While illustrative embodiments have been illustrated and described, it will be appreciated that various changes can be made therein without departing from the spirit and scope of the invention.

1. A luminescent solar concentrator comprising a plurality of waveguides,
said plurality of waveguides comprising at least one first isotropic waveguide and at least one first oriented waveguide,
said first isotropic waveguide comprising an isotropic plurality of first luminophores, each having a first absorption wavelength and a first emission wavelength,
said first oriented waveguide comprising an oriented plurality of second luminophores, each having a second absorption wavelength and a second emission wavelength.

2. The luminescent solar concentrator of claim 1, wherein the second emission wavelength is longer than the first emission wavelength.

3. The luminescent solar concentrator of claim 1, wherein the first oriented waveguide is in optical communication with the first isotropic waveguide.

4. The luminescent solar concentrator of claim 1 further comprising a third waveguide in optical communication with at least one of the first isotropic waveguide and the first oriented waveguide, wherein the third waveguide is selected from the group consisting of an oriented waveguide comprising an oriented plurality of third luminophores, and an isotropic waveguide comprising an isotropic plurality of the third luminophores, said third luminophore each having a third absorption wavelength and a third emission wavelength.

5. The luminescent solar concentrator of claim 1, wherein the first isotropic waveguide further comprises a plurality of third luminophores each having a third absorption wavelength and a third emission wavelength, wherein the third luminophores are selected from the group consisting of isotropic and oriented.

6. The luminescent solar concentrator of claim 1, wherein the oriented plurality of second luminophores are aligned along a director axis selected from the group consisting of a long molecular axis of each luminophore, an absorption dipole of each luminophore, and an emission dipole of each luminophore.

7. The luminescent solar concentrator of claim 1, wherein the oriented plurality of second luminophores are oriented with regard to their emission dipole at a first angle in relation to a major surface of the first oriented waveguide.

8. The luminescent solar concentrator of claim 7, wherein the first angle is from 45 to 90 degrees.

9. The luminescent solar concentrator of claim 1, wherein the oriented plurality of second luminophores are oriented with regard to their absorption dipole at a second angle in relation to a major surface of the first oriented waveguide.

10. The luminescent solar concentrator of claim 9, wherein the second angle is from 0 to 90 degrees.

11. The luminescent solar concentrator of claim 1, further comprising a core waveguide comprising the first isotropic waveguide.

12. The luminescent solar concentrator of claim 11, wherein the core waveguide and the first oriented waveguide are planar waveguides arranged in a stack.

13. The luminescent solar concentrator of claim 11 further comprising a second oriented waveguide comprising an oriented plurality of fourth luminophores, each having a fourth absorption wavelength and a fourth emission wavelength, wherein the second oriented waveguide is in optical communication with the core waveguide, and wherein the core waveguide is intermediate the first oriented waveguide and the second oriented waveguide.

14. The luminescent solar concentrator of claim 13, wherein the fourth luminophores are the same composition and aligned along the same director axis as the second luminophores.

15. The luminescent solar concentrator of claim 1, wherein the luminescent solar concentrator is a collector waveguide for a tandem-waveguide luminescent solar concentrator comprising the collector waveguide and a transport waveguide optically coupled to the collector waveguide, wherein the transport waveguide provides reduced optical loss when compared to the collector waveguide.

16. The luminescent solar concentrator of claim 1, wherein the aligned luminophores are aligned using a method selected from the group consisting of field-induced alignment, extrusion, and mechanical stretching.

17. The luminescent solar concentrator of claim 1 further comprising a photovoltaic device in optical communication with at least the first oriented waveguide.

18. A method for generating electric power comprising illuminating the luminescent solar concentrator of claim 17 with electromagnetic radiation.

19. The method of claim 18, wherein the electromagnetic radiation comprises the first luminophore absorption peak wavelength.
